(19) United States
(12) Patent Application Publication
(10) Pub. No.: US 2026/0233988 A1
(43) Pub. Date: Aug. 13, 2026

(54) AIRTIGHT STRUCTURE, METHOD FOR MANUFACTURING SAME, AND BASE RESIN COMPOSITION FOR MAINTAINING AIRTIGHTNESS

(71) Applicant: Resonac Corporation, Minato-ku, Tokyo (JP)

(72) Inventors: Seiji KAI, Minato-ku, Tokyo (JP); Tomohito MOROSAKI, Minato-ku, Tokyo (JP); Masayoshi NISHIMOTO, Minato-ku, Tokyo (JP)

(21) Appl. No.: 19/152,569

(22) PCT Filed: Feb. 3, 2023
(86) PCT No.: PCT/JP2023/003670

§ 371 Date: Jul. 31, 2025

(51) Int. Cl. B81B 7/00; B81C 1/00; C23C 16/04; C23C 16/40

(52) U.S. Cl. CPC B81B 7/0038; B81C 1/00285; C23C 16/042; C23C 16/403; B81C 2201/0176; B81C 2203/0136; B81C 2203/019

(57) ABSTRACT

The airtight structure body of the disclosure has an airtight section, an underlying layer that covers an edge section of the airtight section and that includes a resin cured product, and an ALD layer that covers the underlying layer.

### TECHNICAL FIELD

The present disclosure relates to an airtight structure body and a production method thereof, and an underlying resin composition for airtight holding.

### BACKGROUND ART

In recent years, examples of fine structure bodies such as MEMS (MicroElectro Mechanical System) contained in hollow structures holding airtightness have likely increased. The interiors of hollow structures are spaces shielded from the exterior, and fine structure bodies contained in such spaces are insulated from the external environment. As specific examples of structure bodies that hold airtightness, structure bodies such as gyroscope sensors, acceleration sensors, SAW (Surface Acoustic Wave)-BAW (Bulk Acoustic Wave) filters, flow path chips, optical waveguide elements, or optical elements are also known.

A method is exemplified in which an ALD layer with an atomic layer deposition (ALD) process is disposed outside a hollow structure in order to maintain airtightness of the hollow structure (see, for example, Patent Literature 1).

### CITATION LIST

### Patent Literature

Patent Literature 1: Japanese National-Phase Publication (JP-A) No. 2016-511535

### SUMMARY OF INVENTION

### Technical Problem

A hollow structure can be formed by, for example, metal-joining top sections of side wall frames respectively provided on paired substrates and each made of Au or a Sn—Cu alloy, or providing a resin rib between paired substrates with a permanent resist as a resin material.

However, such metal-joining of top sections of metallic side wall frames may cause the occurrence of fine voids on a joined surface. In a case in which these voids penetrate through the inside and outside of the hollow structure, airtightness in the hollow structure is impaired. Also in a case in which the hollow structure is formed by forming a resin rib on one of the paired substrates and contacting the top of the rib with the other of the paired substrates, the top of the rib, which is not smooth, causes the occurrence of pores penetrating the inside and outside of the hollow structure, on a contact section between the rib and the substrates, and airtightness in the hollow structure is impaired. In addition, fine cracks may occur on the resin rib, and such fine cracks can cause airtightness in the hollow structure to be impaired.

ALD can allow for formation of a flat and dense thin film by control of the thickness of an atomic layer. The film formation rate is about 0.11 nm per cycle even in the case of common aluminum oxide (AL₂O₃) according to the principle of ALD, and corresponds to from 100 nm to 300 nm per hour, and such formation is very time-consuming. Therefore, it is not realistic to maintain airtightness of the hollow structure only with an ALD thin film whose film formation is time-consuming.

The disclosure has been made in view of the above conventional circumstances, and an object thereof is to provide an airtight structure body excellent in airtightness and a production method thereof. Another object of the disclosure is to provide an underlying resin composition for airtight holding, to be used for producing an airtight structure body excellent in airtightness.

### Solution to Problem

Specific solutions for achieving the above objects are as follows.
<1> An airtight structure body including an airtight section, an underlying layer that covers an edge section of the airtight section and that includes a resin cured product, and an ALD layer that covers the underlying layer.
<2> The airtight structure body according to <1>, wherein a glass transition temperature of the resin cured product is from 150° C. to 400° C.
<3> The airtight structure body according to <1> or <2>, wherein a 5% weight loss temperature of the resin cured product is from 250° C. to 400° C.
<4> The airtight structure body according to any one of <1> to <3>, wherein a storage elastic modulus at 165° C. of the resin cured product is from 10 MPa to 50 GPa.
<5> The airtight structure body according to any one of <1> to <4>, wherein a coefficient of linear expansion of the resin cured product is from 0 ppm/K to 100 ppm/K.
<6> The airtight structure body according to any one of <1> to <5>, wherein a difference between a coefficient of linear expansion of the resin cured product and a coefficient of linear expansion of the ALD layer is from 0 ppm/K to 30 ppm/K.
<7> The airtight structure body according to any one of <1> to <6>, wherein the airtight section is formed by a first cover substrate, a second cover substrate, and a wall member that joins the first cover substrate and the second cover substrate to separate an inside and an outside of the airtight section.
<8> The airtight structure body according to <7>, wherein the wall member includes a metal.
<9> The airtight structure body according to <7>, wherein the wall member includes a resin.
<10> The airtight structure body according to any one of <1> to <9>, wherein an interior of the airtight section is filled with an inert gas.
<11> The airtight structure body according to any one of <1> to <10>, wherein the ALD layer includes Al₂O₃.
<12> A method of producing an airtight structure body, including covering an edge section of an airtight section with a curable resin composition to form a curable resin composition layer, curing the curable resin composition layer to form an underlying layer, and forming an ALD layer that covers the underlying layer.
<13> The method of producing an airtight structure body according to <12>, wherein the curable resin composition has thermosetting properties.
<14> The method of producing an airtight structure body according to <12> or <13>, wherein the curable resin composition is a positive photosensitive resin composition.
<15> The method of producing an airtight structure body according to any one of <12> to <14>, wherein the airtight section is formed by using a first cover substrate in which a metallic first side wall frame is provided on one surface of the first cover substrate and a second cover substrate in which a metallic second side wall frame is provided on one surface of the second cover substrate, to join a top section of the first side wall frame and a top section of the second side wall frame.
<16> An underlying resin composition for airtight holding, including a curable component.
<17> The underlying resin composition for airtight holding according to <16>, wherein the underlying resin composition is a positive photosensitive resin composition.
<18> The underlying resin composition for airtight holding according to <16>, wherein the underlying resin composition is a negative photosensitive resin composition.

### Advantageous Effects of Invention

The disclosure can provide an airtight structure body excellent in airtightness and a production method thereof. The disclosure can also provide an underlying resin composition for airtight holding, to be used for producing an airtight structure body excellent in airtightness.

### BRIEF DESCRIPTION OF DRAWINGS

FIG. 1A A plan view of an airtight structure body 10.

FIG. 1B An A-A-line cross-sectional view of the airtight structure body 10.

FIG. 1C An A-A-line cross-sectional view of another aspect of the airtight structure body 10.

FIG. 1D An A-A-line cross-sectional view of another aspect of the airtight structure body 10.

FIG. 2A A plan view of an airtight structure body 30.

FIG. 2B A B-B-line cross-sectional view of the airtight structure body 30.

FIG. 3A A plan view of an airtight structure body 40.

FIG. 3B A C-C-line cross-sectional view of the airtight structure body 40.

FIG. 4A A plan view of an airtight structure body 50.

FIG. 4B A D-D-line cross-sectional view of the airtight structure body 50.

### DESCRIPTION OF EMBODIMENTS

Hereinafter, the disclosure is described in detail. Herein, the disclosure is not limited to the following embodiment. In the following embodiments, any constituent component (also encompassing an element step and the like) is not essential except in a case particularly clearly indicated. The same also applies to any numerical value and any range thereof, and the disclosure is not restricted thereto.

In the disclosure, the term “step” encompasses not only an independent step from other steps, but also a step that achieves the object of the relevant step even in the case of being clearly indistinguishable from such other steps.

In the disclosure, a numerical value range expressed with “(from) . . . to” includes numerical values described before and after “to” respectively as the minimum value and the maximum value.

The upper limit value or the lower limit value in one numerical value range among numerical value ranges described stepwise in the disclosure may be replaced with the upper limit value or the lower limit value in another numerical value range described stepwise among them.

In the disclosure, each component may include a plurality of corresponding substances. In a case in which a plurality of substances corresponding to each component is present in a composition, the content rate or content of each component means the total content rate or content of the plurality of substances present in the composition, unless particularly noted.

In the disclosure, the term “layer” or “film” encompasses not only a case in which the layer or film is formed in the entire of a region in which the layer or film is present, but also a case in which the layer or film is formed in only one portion of the region, in observation of the region.

In the disclosure, the “(meth)acryloyl group” means at least one of an acryloyl group or a methacryloyl group, and the “(meth)acrylic” means at least one of acrylic or methacrylic.

In the disclosure, the average thickness of a layer or film is a value provided as an arithmetic average value determined by measuring the thicknesses at 5 points of an objective layer or film.

The thickness of a layer or film can be measured with a micrometer or the like. In the disclosure, in a case in which the thickness of a layer or film can be directly measured, the thickness is measured with a micrometer. In this regard, in which the thickness of one layer or the total thickness of a plurality of layers is measured, such a thickness may be measured by observing a cross section of a measurement object with an electron microscope.

### <Airtight Structure Body>

The airtight structure body of the disclosure has an airtight section, an underlying layer that covers an edge section of the airtight section and that includes a resin cured product, and an ALD layer that covers the underlying layer.

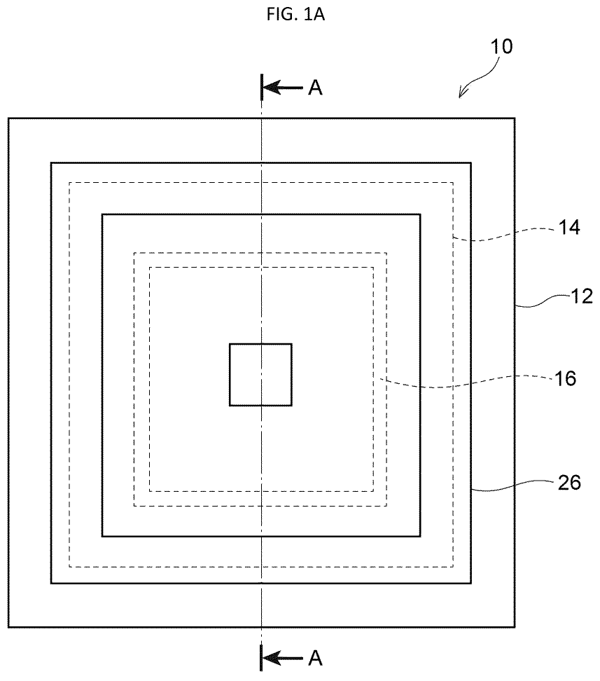

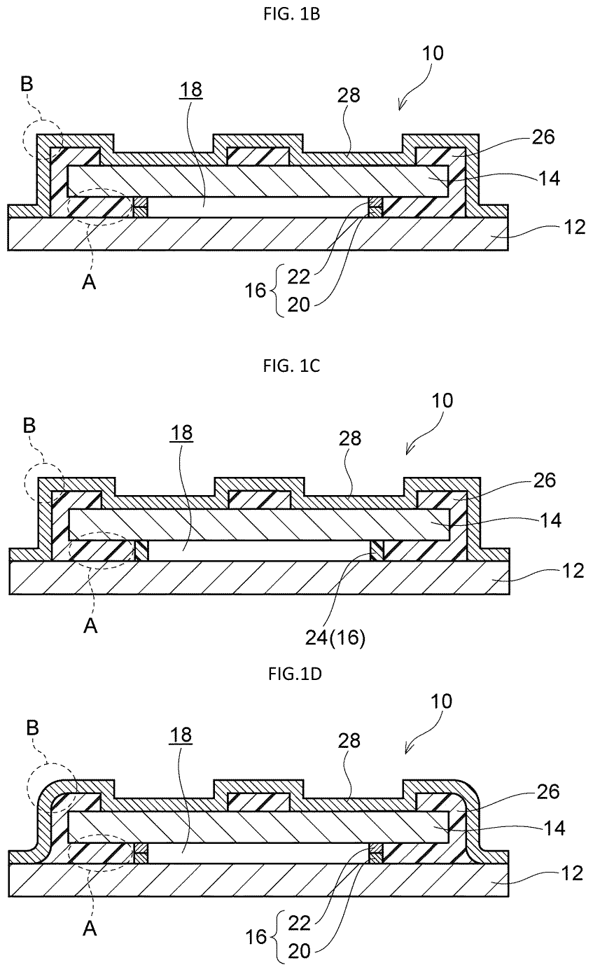

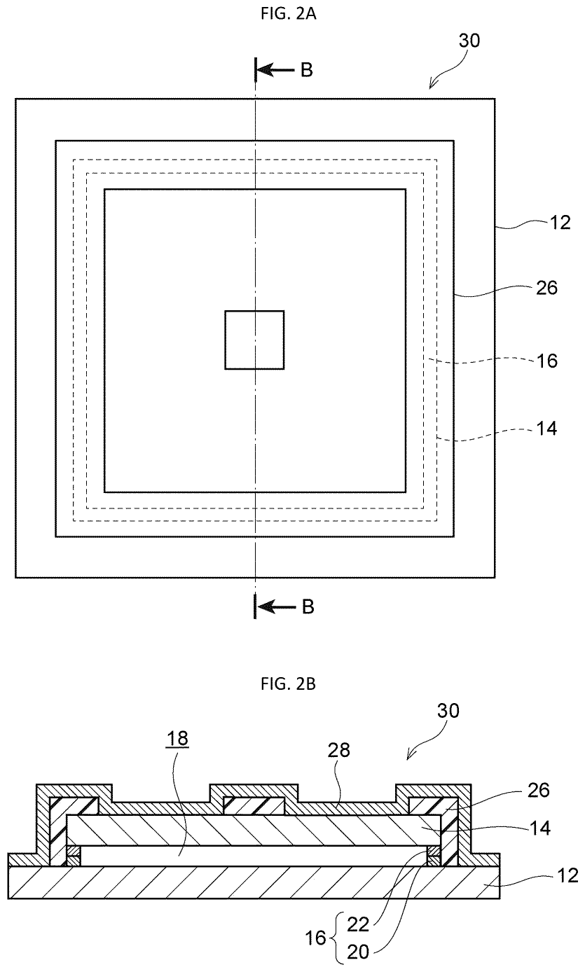

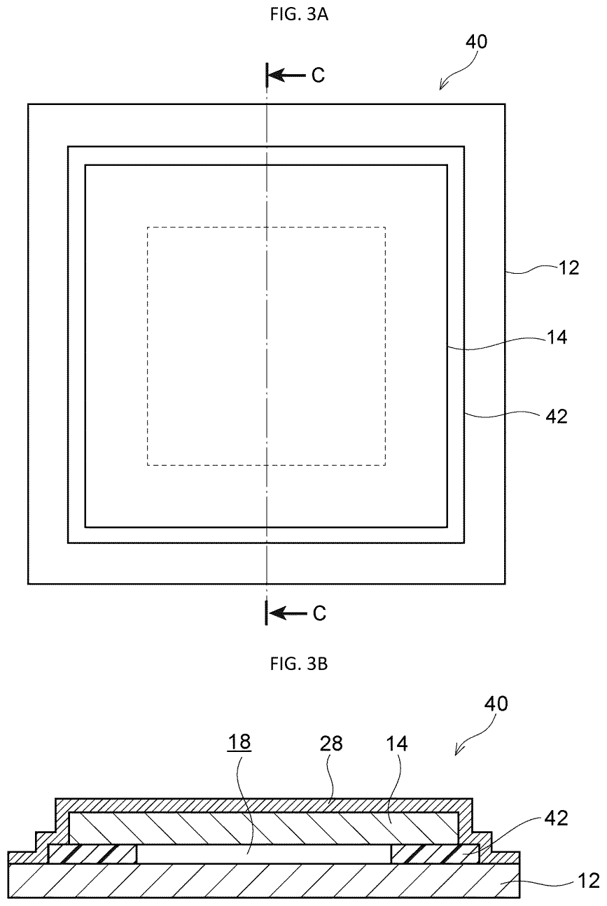

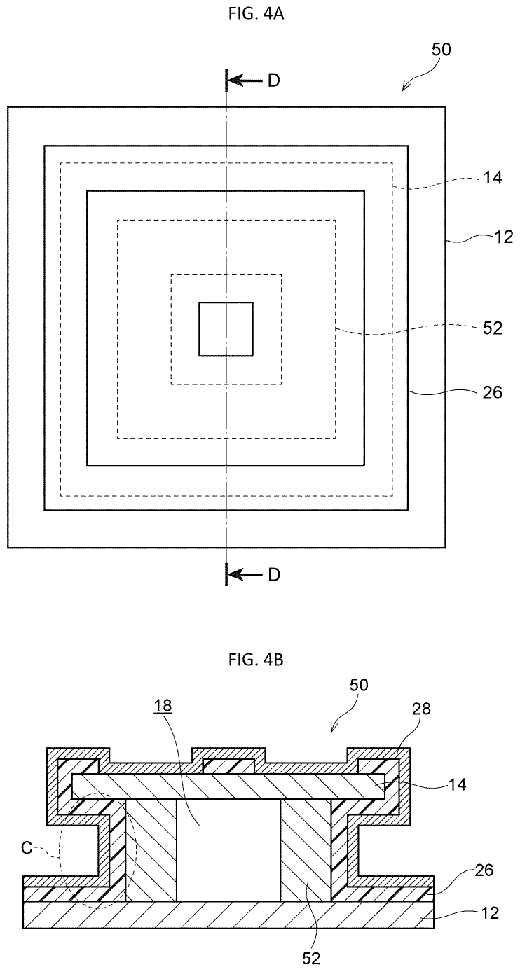

Hereinafter, embodiments of the airtight structure body of the disclosure and embodiments of the method of producing the airtight structure body of the disclosure are described in detail with reference to the drawings. The description of the ALD layer is omitted here in FIG. 1A, FIG. 2A, FIG. 3A and FIG. 4A, for clarity.

In the following description, the same or corresponding section is marked with the same symbol and the description thereof overlapped may be omitted. Each dimensional ratio in the drawings is not limited to any ratio illustrated.

### First Embodiment

FIG. 1A is a plan view illustrating a first embodiment of the airtight structure body of the disclosure. FIG. 1B is an A-A-line cross-sectional view in FIG. 1A.

An airtight structure body 10 illustrated in FIG. 1A and FIG. 1B has an airtight section 18 formed by a first cover substrate 12, a second cover substrate 14, and a wall member 16 that joins the first cover substrate 12 and the second cover substrate 14. The wall member 16 is taken with the first cover substrate 12 and the second cover substrate 14 to separate the inside and the outside of the airtight section 18, and is provided inside against the outer peripheral edge of the second cover substrate 14.

The wall member 16 is provided inside against the outer peripheral edge of the second cover substrate 14, whereby a region A in which the second cover substrate 14 overhangs the first cover substrate 12 occurs.

The wall member 16 is formed by, for example, joining a top section of a metallic first side wall frame 20 provided on one surface of the first cover substrate 12 and a top section of a metallic second side wall frame 22 provided on one surface of the second cover substrate 14. Examples of the method of joining the top section of the first side wall frame 20 and the top section of the second side wall frame 22 include methods such as metal joining, surface activated joining, anode joining, and thermal diffusion joining.

In a case in which the first side wall frame 20 and the second side wall frame 22 are each made of a metal, examples of the metals included in the first side wall frame 20 and the second side wall frame 22 include Au, Cu, a Sn—Cu alloy, and a Sn—Ag alloy. Each of the metals included in the first side wall frame 20 and the second side wall frame 22 may be Cu or Au, and Cu—Cu joining or Au—Au joining may be performed.

The first side wall frame 20 and the second side wall frame 22 are each made of a metal, whereby the wall member 16, which includes a metal, is obtained.

In another aspect, the wall member 16 can also be formed by contacting a top section of a third side wall frame 24 that is provided on one surface of the first cover substrate 12 and that is made of a resin, with on one surface of the second cover substrate 14, and joining the top section of the third side wall frame 24 to the one surface of the second cover substrate 14 by, if necessary, heating and pressurizing, as illustrated in FIG. 1C. The side wall frame 24 is made of a resin, whereby the wall member 16, which includes a resin, is obtained. Examples of the resin included in the third side wall frame 24 include a polyimide resin, a polyamideimide resin, a polybenzoxazole resin, an epoxy resin, a (meth)acrylic resin, and an olefin resin.

In a case in which photosensitivity can be imparted to the resin, a desirable effect such as pattern formability or shortening in throughput (takt time of each step) is obtained. Therefore, the resin preferably contains a reactive functional group. Examples of the reactive functional group include an amino group, an amide group, an imide group, a hydroxyl group, an aldehyde group, a ketone group, a carboxy group, a (meth)acryloyl group, an ester group, an ether group, an alkenyl group, and an alkynyl group.

A photopolymerization initiator or the like may be contained in the resin in order to impart photosensitivity.

The thickness of the wall member 16 is appropriately set depending on the intended use of the airtight structure body, and may be, for example, from 1 μm to 50 μm.

Examples of each of the first cover substrate 12 and the second cover substrate 14 include substrates of metals such as copper and Al, semiconductor substrates such as a SiC substrate, a sapphire substrate, a GaN substrate, a piezoelectric substrate (lithium tantalate, lithium niobate, or the like), a GaAs substrate, a CdTe substrate, a silicon substrate, a germanium substrate, and a silicon nitride substrate, glass substrates such as a soda glass substrate, an alkali-free glass substrate, a low-expansion glass substrate, and a quartz glass substrate, and plastic substrates such as polyethylene terephthalate.

The average thicknesses of the first cover substrate 12 and the second cover substrate 14 are each appropriately set depending on the intended use of the airtight structure body, and each thereof may be, for example, independently from 5 μm to 1.1 mm.

The distance between the first cover substrate 12 and the second cover substrate 14 (namely, the height of the wall member 16) is appropriately set depending on the intended use of the airtight structure body, and may be, for example, from 5 μm to 500 μm.

The outer peripheral edge of the airtight section 18 is covered with an underlying layer 26 including a resin cured product. The outer peripheral edge of the airtight section 18 can be covered with the underlying layer 26, thereby resulting in an enhancement in airtightness of the airtight section 18 as compared with a case in which the airtight section 18 is covered with only an ALD layer 28 described later.

A corner section B of the underlying layer 26, which covers a peripheral edge of the second cover substrate 14, has a substantially perpendicular cross section. The corner section B may be, for example, in a state in which a corner of the cross section is rounded, as illustrated in FIG. 1D. Such a state in which a corner of the corner section B is rounded easily allows coverage at the corner section B of an ALD layer 28 described later, formed on the underlying layer 26, to be enhanced, and easily allows airtightness to be kept.

The 5% weight loss temperature of the resin cured product included in the underlying layer 26 is mainly supposed to be from 250° C. to 400° C., and is preferably from 300° C. to 350° C. from the viewpoint of suppression of degradation in a heating step during mounting.

The 5% weight loss temperature of the resin cured product can be measured as the temperature at which the weight reduction percentage of a sample as compared with that before heating is 5% as determined in conditions of a nitrogen stream of 100 mL/min and a rate of temperature rise of 10° C./min with about 10 mg of the sample packed in a pan (φ6 mm) made of platinum, by use of a simultaneous differential thermal-thermogravimetric measurement device (for example, “TG/DTA7300” (product name, manufactured by Hitachi High-Tech Science Corporation)).

The storage elastic modulus at 165° C. of the resin cured product included in the underlying layer 26 is preferably from 10 MPa to 50 GPa, more preferably from 1 GPa to 10 GPa from the viewpoint of shape stability of the resin and the ALD layer.

The storage elastic modulus at 165° C. of the resin cured product can be determined by viscoelasticity measurement in a tensile mode with a dynamic viscoelasticity measurement device (for example, RSA GII (manufactured by TA instruments)). Measurement conditions are set to a rate of temperature rise of 10° C./min, a temperature range of from 0° C. to 300° C., a frequency of 10 Hz, and a strain of 0.1%, and the storage elastic modulus at 165° C. is measured.

The glass transition temperature of the resin cured product included in the underlying layer 26 is preferably from 150° C. to 400° C., more preferably from 150° C. to 350° C., still more preferably from 250° C. to 350° C. from the viewpoint of shape stability against the change in temperature.

The glass transition temperature of the resin cured product refers to a value measured as follows.

A test piece of 20 mm×4 mm×4 mm is subjected to measurement of the change in dimension (coefficient of linear expansion) in the longitudinal direction of the test piece in a condition of a rate of temperature rise of 5° C./min with a thermal mechanical analyzer (for example, TAS-1000S manufactured by Rigaku Corporation), and the temperature corresponding to the folding point in the resulting heat expansion curve is defined as the glass transition temperature.

The coefficient of linear expansion of the resin cured product included in the underlying layer 26 is preferably close to those of a substrate material and a material forming the hollow structure from the viewpoint of thermal stress, and is preferably from 0 ppm/K to 100 ppm/K, more preferably from 0 ppm/K to 25 ppm/K. In the disclosure, the coefficient of linear expansion of the resin cured product refers to the coefficient of linear expansion in the temperature region equal to or less than the glass transition temperature of the resin cured product.

The coefficient of linear expansion of the resin cured product refers to a value measured as follows.

The coefficient of linear expansion in the temperature region equal to or less than the glass transition temperature can be determined based on the coefficient of linear expansion determined in the above measurement of the glass transition temperature.

The difference between the coefficient of linear expansion of the resin cured product and the coefficient of linear expansion of the ALD layer is preferably from 0 ppm/K to 30 ppm/K, more preferably from 0 ppm/K to 20 ppm/K from the viewpoint of thermal stress.

Examples of the resin cured product included in the underlying layer 26 include polyimide, polyamideimide, polybenzoxazole, an epoxy resin, a (meth)acrylic resin, polyolefin, polyamide, polyhydroxystyrene, a norbornene resin, and a novolac resin.

In a case in which photosensitivity can be imparted to the resin, a desirable effect such as pattern formability or shortening in throughput (takt time of each step) is obtained. Therefore, the resin preferably contains a reactive functional group. Examples of the reactive functional group include an amino group, an amide group, an imide group, a hydroxyl group, an aldehyde group, a ketone group, a carboxy group, a (meth)acryloyl group, an ester group, an ether group, an alkenyl group, and an alkynyl group.

A photopolymerization initiator or the like may be contained in the resin in order to impart photosensitivity.

The thickness of the underlying layer 26 may be a value that is sufficient for enabling the underlying layer to cover the outer peripheral edge of the airtight section 18.

The thickness of the underlying layer 26 in the thickness direction of the first cover substrate 12 (or second cover substrate 14) may be set so as to be more than the height of the wall member 16.

The thickness of the underlying layer 26 in the surface direction of the second cover substrate 14 may be any thickness at a level in which the edge section of the second cover substrate 14 is covered with the underlying layer 26. In a case in which the edge section of the second cover substrate 14 is covered with the underlying layer 26, an uneven shape derived from the edge section of the second cover substrate 14 can be smoothened. As a result, coverage of an ALD layer 28 provided on the underlying layer 26 is easily enhanced. The thickness of the underlying layer 26 in the surface direction of the second cover substrate 14 here refers to the thickness from the edge section of the second cover substrate 14.

The underlying layer 26 is covered with the ALD layer 28. In other words, the airtight section 18 is dually covered with the underlying layer 26 and the ALD layer 28. Therefore, the airtight structure body of the disclosure is excellent in airtightness of the airtight section 18.

The underlying layer 26 is provided at a lower section of the ALD layer 28 and an underlying member on which the ALD layer 28 is to be formed is smoothened and then the ALD layer 28 is provided, whereby airtightness of the airtight section 18 can be kept even in a case in which the ALD layer 28 is a thin film. As a result, reliability of the airtight structure body is enhanced. The underlying layer 26 and the ALD layer 28 are combined, whereby the ALD layer 28 needs not be formed at a thickness of several micrometers for airtightness securement, airtightness of the airtight section 18 can be secured with the ALD layer 28 thinner (for example, 1 μm or less) than the case of only the ALD layer 28, and productivity of the airtight structure body is enhanced.

The component included in the ALD layer 28 is not particularly limited, and examples include SiO₂, TiO₂, Al₂O₃, ZrO₂, TaN, TiN, SiN, ZnO, and Ta₂O₅. In particular, Al₂O₃ or SiN is preferred, and Al₂O₃ is more preferred.

The average thickness of the ALD layer 28 is not particularly limited, may be a sufficient for allowing the underlying layer 26 to be covered, and may be, for example, from 1 nm to 1 μm.

A structure body not illustrated is accommodated in the airtight section 18. Examples of the structure body include an interdigital electrode, a high-frequency device, and a pressure sensor in MEMS. In particular, the airtight structure body of the disclosure is effective for an enhancement in reliability of a high-frequency device.

The interior of the airtight section 18 may be filled with air, or may be filled with an inert gas such as an argon gas or a nitrogen gas. The interior of the airtight section 18 may be in a vacuum state at the atmospheric pressure or less.

### Second Embodiment

FIG. 2A is a plan view illustrating a second embodiment of the airtight structure body of the disclosure. FIG. 2B is a B-B-line cross-sectional view in FIG. 2A.

An airtight structure body 30 illustrated in FIG. 2A and FIG. 2B has an airtight section 18 formed by a first cover substrate 12, a second cover substrate 14, and a wall member 16 that joins the first cover substrate 12 and the second cover substrate 14. The wall member 16 is provided on a peripheral edge section of the second cover substrate 14. Therefore, a region A in which the second cover substrate 14 overhangs the first cover substrate 12 does not occur as compared with the airtight structure body 10.

The details of the first cover substrate 12, the second cover substrate 14, the wall member 16, the airtight section 18, an ALD layer 28, and an underlying layer 26 included in the airtight structure body 30 are the same as those in the case of the airtight structure body 10.

### Third Embodiment

FIG. 3A is a plan view illustrating a third embodiment of the airtight structure body of the disclosure. FIG. 3B is a C-C-line cross-sectional view in FIG. 3A.

An airtight structure body 40 illustrated in FIG. 3A and FIG. 3B has a first cover substrate 12, a second cover substrate 14, a broad rib 42 made of a resin, in which the rib is placed between the first cover substrate 12 and the second cover substrate 14 to not only form an airtight section 18, but also cover the outer peripheral edge of the airtight section 18, and an ALD layer 28 that covers the first cover substrate 12, the second cover substrate 14, and the broad rib 42.

The broad rib 42 is extended from the inside (side on which the airtight section 18 is present) of the outer peripheral edge of the second cover substrate 14 toward the outside thereof as illustrated in FIG. 3B.

Examples of the resin included in the broad rib 42 include a polyimide resin, a polyamideimide resin, a polybenzoxazole resin, an epoxy resin, a (meth)acrylic resin, and an olefin resin.

In a case in which photosensitivity can be imparted to the resin, a desirable effect such as pattern formability or shortening in throughput (takt time of step) is obtained. Therefore, the resin preferably contains a reactive functional group. Examples of the reactive functional group include an amino group, an amide group, an imide group, a hydroxyl group, an aldehyde group, a ketone group, a carboxy group, a (meth)acryloyl group, an ester group, an ether group, an alkenyl group, and an alkynyl group.

A photopolymerization initiator or the like may be contained in the resin in order to impart photosensitivity.

The average thickness of the broad rib 42 is appropriately set depending on the intended use of the airtight structure body, and may be, for example, from 1 μm to 150 μm.

The details of the first cover substrate 12, the second cover substrate 14, the airtight section 18, and the ALD layer 28 included in the airtight structure body 40 are the same as those in the case of the airtight structure body 10.

### Fourth Embodiment

FIG. 4A is a plan view of a fourth embodiment of the airtight structure body of the disclosure. FIG. 4B is a D-D-line cross-sectional view in FIG. 4A.

An airtight structure body 50 illustrated in FIG. 4A and FIG. 4B has an airtight section 18 formed by a first cover substrate 12, a second cover substrate 14, and a wall member 52 that joins the first cover substrate 12 and the second cover substrate 14. The wall member 52 is taken with the first cover substrate 12 and the second cover substrate 14 to separate the inside and the outside of the airtight section 18, and is provided inside against the outer peripheral edge of the second cover substrate 14

The wall member 52 included in the airtight structure body 50 is formed at a high position in the thickness direction of the first cover substrate 12 (or second cover substrate 14) as compared with the wall member 16 included in the airtight structure body 10. Therefore, an underlying layer 26 can be provided at a more uniform thickness on a surface of the wall member 52 in a region C in which the second cover substrate 14 overhangs the first cover substrate 12.

The details of the first cover substrate 12, the second cover substrate 14, the airtight section 18, an ALD layer 28, and the underlying layer 26 included in the airtight structure body 50 are the same as those in the case of the airtight structure body 10.

The wall member 52 in the airtight structure body 50 may be made of a resin or a metal. The height of the wall member 52 may be a value so that the underlying layer 26 is formed on a surface of the wall member 52, and is not particularly limited. The thickness of the wall member 52 may be a value so that the structure of the wall member 52 can be maintained, and is not particularly limited.

Although the airtight structure body of the disclosure is described above based on the first embodiment to fourth embodiment, the airtight structure body of the disclosure is not limited to the above configurations. For example, the airtight section 18 is a hollow structure in the above embodiment, whereas the airtight section 18 may also be a solid structure as in an optical waveguide included in an optical waveguide element.

The airtight structure body of the disclosure, in which the edge section of the airtight section is covered with the underlying layer including the resin cured product and furthermore the underlying layer is covered with the ALD layer, thus is excellent in airtightness of the airtight section. Furthermore, the airtight section is enhanced in airtightness and thus thermal reliability is enhanced.

The airtight structure body of the disclosure, in which the ALD layer is formed on the underlying layer, thus allows for decrease of a corner section in which stress is easily collected, and is enhanced in mechanical reliability.

### <Method of Producing Airtight Structure Body>

The method of producing the airtight structure body of the disclosure is not particularly limited, and the airtight structure body of the disclosure may be produced with a combination of known various procedures.

In order to simply produce the airtight structure body excellent in airtightness of the disclosure, the method of producing the airtight structure body of the disclosure (hereinafter, sometimes referred to as “production method of the disclosure”.) may include covering an edge section of an airtight section with a curable resin composition to form a curable resin composition layer, curing the curable resin composition layer to form an underlying layer, and forming an ALD layer that covers the underlying layer.

Hereinafter, each step of the production method of the disclosure is described.

A curable resin composition layer is formed by covering an edge section of an airtight section with a curable resin composition in the production method of the disclosure.

The type of the airtight section is not particularly limited, and may be a hollow structure or a solid structure as described above.

The curable resin composition layer may be formed by, for example, using a liquid curable resin composition and adopting a known application method to apply the curable resin composition so that the edge section of the airtight section is covered.

Examples of the method of applying the curable resin composition include a knife coating method, a roll coating method, a spray coating method, a gravure coating method, a bar coating method, a curtain coating method, a blade coating method, a doctor coating method, a spin coating method, a screen printing method, and an ink-jet method. The curable resin composition layer may also be formed by use of a lamination method, a resin CVD method, or the like with a film resist.

In a case in which the curable resin composition includes a solvent, at least one portion of the solvent may be removed from the curable resin composition by subjecting the curable resin composition layer to a drying treatment. Examples of the drying treatment include heating drying, natural drying, and freeze-drying, under ordinary pressure or under reduced pressure.

The underlying layer is formed by curing the curable resin composition layer. Curing conditions and the curing method of the curable resin composition layer are not particularly limited, and are appropriately selected depending on the type or the like of the curable component included in the curable resin composition.

In a case in which the curable resin composition has thermosetting properties, the underlying layer can be formed by heating the curable resin composition layer to cure the curable resin composition layer. The heating temperature, heating conditions, and the like for curing the curable resin composition layer are appropriately selected. In a case in which the curable resin composition has photo-curing properties, the underlying layer can be formed by irradiating the curable resin composition layer with light to cure the curable resin composition layer. The amount of exposure for curing the curable resin composition layer is appropriately set.

In order to enable the underlying layer to be formed on a desired position, a positive photosensitive resin composition or a negative photosensitive resin composition may be used as the curable resin composition. In a case in which a structure in which the second cover substrate 14 overhangs the first cover substrate 12, as in the region A illustrated in FIG. 1B, is present in the edge section of the airtight section, the curable resin composition present in the region A is easily in the state of being still unexposed in the case of light irradiation from the second cover substrate 14 side. Therefore, in the case of the airtight structure body in which the region A occurs, a positive photosensitive resin composition is preferably used in order to inhibit an unexposed area of the curable resin composition from being removed by development. In this regard, in the case of the airtight structure body in which the region A does not occur, any of a positive photosensitive resin composition or a negative photosensitive resin composition may be used.

The underlying layer can be formed on a desired position by using a positive photosensitive resin composition or a negative photosensitive resin composition to form the curable resin composition layer, subjecting the curable resin composition layer to pattern exposure and development with a developer to provide a desired resin pattern to the curable resin composition layer, thereby providing a patterned resin film, and then heat-treating the patterned resin film.

The pattern exposure is exposed to a predetermined pattern with, for example, a photomask being interposed.

Examples of the active ray for irradiation include an i-line, and broadband ultraviolet light, visible light, and radiation, and an i-line is preferred. The exposure apparatus used here can be a parallel exposure machine, a projection exposure machine, a stepper, a scanner exposure machine, or the like.

After the exposure, development can be made to provide a patterned resin film that is a patterned curable resin composition layer. In a case in which the curable resin composition is a negative photosensitive resin composition, an unexposed area is removed by a developer.

A good solvent of the curable resin composition layer can be used singly, or the good solvent and a poor solvent can be appropriately mixed and used as the organic solvent usable as the negative developer.

Examples of the good solvent include N-methyl-2-pyrrolidone, N-acetyl-2-pyrrolidone, N,N-dimethylacetamide, N,N-dimethylformamide, dimethylsulfoxide, γ-butyrolactone, α-acetyl-γ-butyrolactone, 3-methoxy-N, N-dimethylpropaneamide, cyclopentanone, cyclohexanone, and cycloheptanone.

Examples of the poor solvent include toluene, xylene, methanol, ethanol, isopropanol, propylene glycol monomethyl ether acetate, propylene glycol monomethyl ether, and water.

In a case in which the curable resin composition is a positive photosensitive resin composition, an exposed area is removed by a developer.

Examples of the solution used as the positive developer include a tetramethylammonium hydroxide (TMAH) solution and a sodium carbonate solution.

The negative developer or the positive developer may include a surfactant. The content of the surfactant is preferably from 0.01 parts by mass to 10 parts by mass, more preferably from 0.1 parts by mass to 5 parts by mass based on 100 parts by mass of the developer.

The development time can be, for example, a time twice the time from immersion of the curable resin composition layer in the developer to complete dissolution of the curable resin composition layer.

The development time may be regulated depending on the component included in the curable resin composition layer, and is, for example, preferably from 10 seconds to 15 minutes, more preferably 10 seconds to 5 minutes, and is still more preferably from 20 seconds to 5 minutes from the viewpoint of productivity.

The patterned resin film after development may be washed with a rinse liquid.

Distilled water, methanol, ethanol, isopropanol, toluene, xylene, propylene glycol monomethyl ether acetate, propylene glycol monomethyl ether, or the like may be used singly, or may appropriately mixed and used, or may be combined stepwise and used as the rinse liquid.

The patterned resin film can be heated, thereby forming a patterned underlying layer on a desired position. The heating temperature, heating conditions, and the like of the patterned resin film are appropriately selected.

The underlying layer may be formed by providing the curable resin composition on a position in which the underlying layer is required, of the edge section of the airtight section, to cure the curable resin composition by heating or light irradiation.

The method of providing the curable resin composition on the position in which the underlying layer is required is not particularly limited, and a conventionally known method can be adopted. Examples of the method of providing the curable resin composition on the position in which the underlying layer is required include a lamination method with a film resist, a resin CVD method, an ink-jet method, a screen printing method with a screen mask opening at the position in which the underlying layer is required, and imprint.

The underlying layer may also be formed on a desired position by forming the underlying layer so that the entire surface of the airtight section is covered with the curable resin composition, and then removing an unnecessary underlying layer by a procedure such as dry etching, wet etching, ion milling, dicing, or lifting-off after resin vapor-deposition.

An ALD layer is formed on the underlying layer so as to cover the underlying layer.

ALD is a method including depositing an atomic layer one-by-one by sequentially performing loading of a raw material gas and loading of a reduction gas with purging being interposed, and the types of the raw material gas and the reduction gas are appropriately selected depending on the component included in the ALD layer formed. For example, in a case in which the ALD layer includes Al₂O₃, the raw material gas and the reduction gas are, for example, respectively trimethylaluminum and water.

Various conditions, for example, the flow rates of the gases, temperature conditions, the feeding times of the gases, the treatment substrate temperature, and the pressure in a chamber in formation of the ALD layer are appropriately set in consideration of the component included in the ALD layer formed, the average thickness of the ALD layer, and/or the like.

The temperature of the underlying layer during formation of the ALD layer may be 125° C. or more in order to prevent cracks from occurring on the ALD layer through a heat history due to the difference in coefficient of linear expansion between the ALD layer and the underlying layer in the production method of the disclosure. In general, ceramics included in ALD layers, while tend to be robust over a compression load, tend to be vulnerable to a tensile load. The ALD layer is formed in a state in which the underlying layer is heated to 125° C. or more, whereby a state is maintained in which the ALD layer is also shrunk according to shrink of the underlying layer due to a decrease in temperature of the underlying layer. Such a state in which the ALD layer is shrunk is maintained, whereby a tensile load applied to the ALD layer is easily relaxed and cracks hardly occur on the ALD layer in a case in which expansion of the underlying layer occurs again due to an increase in temperature. Therefore, reliability of the airtight structure body is easily enhanced.

The temperature of the underlying layer during formation of the ALD layer may be 350° C. or less in order to suppress degradation or the like of the airtight structure body due to heat.

The ALD layer is formed on the underlying layer so as to cover the underlying layer in the production method of the disclosure. The underlying layer and the ALD layer are combined, whereby airtightness of the airtight section is secured. Therefore, the thickness of the ALD layer can be thinner as compared with a case in which airtightness of the airtight section is secured with the ALD layer singly. As a result, a reduction in formation time of the ALD layer is realized.

The airtight structure body of the disclosure is produced through the above steps. The production method of the disclosure can allow for an enhancement in reliability of the airtight structure body and furthermore can allow for a reduction in formation time of the ALD layer.

The production method of the disclosure may include any other step than the above steps.

In the disclosure, the airtight section may be one formed by any method, and the production method thereof is not particularly limited.

The airtight section can be formed by, for example, using a first cover substrate 12 in which a metallic first side wall frame 20 is provided on one surface of the substrate and a second cover substrate 14 in which a metallic second side wall frame 22 is provided on one surface of the substrate, to join a top section of the first side wall frame 20 and a top section of the metallic second side wall frame 22, as illustrated in FIG. 1B.

The method of joining the top section of the first side wall frame 20 and the top section of the metallic second side wall frame 22 is not particularly limited, and a method such as metal joining, surface activated joining, anode joining, or thermal diffusion joining can be used.

The production apparatus for carrying out the method of the disclosure is not particularly limited. The method of the disclosure may be carried out with a plurality of production apparatuses, for example, an application apparatus for providing the curable resin composition so that the edge section of the airtight section is covered, a drier for removing at least one portion of the solvent from the curable resin composition, a curing apparatus for curing the curable resin composition layer in a patterned shape through exposure, development, heating, and the like, and a film formation apparatus for forming the ALD layer. The method of the disclosure may also be carried collectively in one apparatus including an application unit, a drying unit, a curing unit, and a film formation unit.

### <Underlying Resin Composition for Airtight Holding>

The underlying resin composition for airtight holding of the disclosure (hereinafter, sometimes referred to as “composition of the disclosure.) includes a curable component. The composition of the disclosure may be a positive photosensitive resin composition or a negative photosensitive resin composition. The composition of the disclosure may also be a thermosetting resin composition, a photo-curable resin composition, or the like not having development ability.

In the disclosure, the “curable component” refers to a component having the property of being cured by application of light irradiation or heating. The curable component may be a component that is cured itself by light irradiation or heating, or a component that is cured by action of an acid generator, an acid component generated from a radical polymerization initiator, a radical component, or the like.

The resin cured product included in the underlying layer included in the airtight structure body may be a cured product of the composition of the disclosure.

Hereinafter, the detail of the composition of the disclosure is described with, as an example, a case in which the composition of the disclosure is a positive photosensitive resin composition.

The positive photosensitive resin composition may include (A) an alkali-soluble resin, (B) a thermosetting resin, and (C) a photosensitizer.

### (Component (A): Alkali-Soluble Resin)

The alkali-soluble resin is not particularly limited, and is preferably one having high electrical insulation. Examples can include polyimide, a polyimide precursor, polybenzoxazole, a polybenzoxazole precursor, polyamide, polyamideimide, polyhydroxystyrene, a novolac resin, a norbornene resin, an epoxy resin, and a (meth)acrylic resin.

The alkali-soluble resin used here is preferably polyimide, a polyimide precursor, polybenzoxazole, a polybenzoxazole precursor, a novolac resin, or polyhydroxystyrene, more preferably at least one of a polyimide precursor or a polybenzoxazole precursor, particularly from the viewpoint that both insulation and mechanical properties are satisfied.

The alkali-soluble resin is usually developed with an aqueous alkali solution. Therefore, the resin is preferably soluble in an aqueous alkali solution.

Examples of the aqueous alkali solution include an aqueous organic ammonium solution such as an aqueous tetramethylammonium hydroxide (TMAH) solution, an aqueous metal hydroxide solution, an aqueous carbonic acid salt solution, and an aqueous organic amine solution. In general, an aqueous TMAH solution having a concentration of 2.38% by mass is preferably used. Accordingly, the component (A) is preferably soluble in an aqueous TMAH

### Solution

One standard in which the component (A) is soluble in an aqueous alkali solution is described below. After the component (A) is dissolved in any solvent to provide a solution, a substrate such as a silicon wafer is spin-coated with the solution to form a resin film having a thickness of about 5 μm. This film is immersed in any one of an aqueous TMAH solution, an aqueous metal hydroxide solution, an aqueous carbonic acid solution, or an aqueous organic amine solution at from 20° C. to 25° C. As a result, in a case in which a solution is obtained by dissolution, the component (A) used is determined to be soluble in an aqueous alkali solution.

The molecular weight of the component (A) is not particularly limited, and is, for example, preferably from 10,000 to 200,000, more preferably from 12,000 to 100,000 in terms of weight average molecular weight.

The weight average molecular weight can be measured by a gel permeation chromatographic method, and can be determined by conversion with a standard polystyrene calibration curve.

The dispersity obtained by dividing the weight average molecular weight by the number average molecular weight is preferably from 1.0 to 4.0, more preferably from 1.0 to 3.5.

### —Polyimide Precursor—

The polyimide precursor is preferably at least one resin selected from the group consisting of polyamide acid, a polyamide acid ester, a polyamide acid salt, and polyamide acid amide. The polyamide acid ester and the polyamide acid amide are each a compound in which at least some hydrogen atoms in carboxy groups in polyamide acid are replaced with monovalent organic groups, and the polyamide acid salt is a compound in which at least some carboxy groups in polyamide acid are taken with a basic compound having a pH of 7 or more to form a salt structure.

The polyimide precursor may include a compound having a structural unit represented by the following Formula (I).

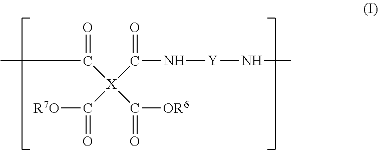

In Formula (I), X represents a tetravalent organic group, and Y represents a divalent organic group. Each of R⁶ and R⁷ independently represents a hydrogen atom or a monovalent organic group, and at least one of R⁶ or R⁷ optionally has a polymerizable unsaturated bond.

The polyimide precursor may have a plurality of the above structural units represented by Formula (I), and Xs, Ys, R's and R⁷s in such plural structural units may be each the same as or different from each other.

A combination of R⁶ and R⁷ is not particularly limited as long as each thereof is independently a hydrogen atom, or a monovalent organic group. For example, at least one of R⁶ or R⁷ may be a hydrogen atom and the other thereof may be a monovalent organic group described later, both thereof may be monovalent organic groups that are the same as or different from each other, or both thereof may be hydrogen atoms. In a case in which the polyimide precursor has a plurality of the above structural units represented by Formula (I) as described above, the respective combinations of R⁶ and R⁷ in such structural units may be the same as or different from each other.

In Formula (I), the number of carbon atoms in the tetravalent organic group represented by X is preferably from 4 to 25, more preferably from 5 to 13, still more preferably from 6 to 12.

The tetravalent organic group represented by X may include an aromatic ring from the viewpoint of heat resistance. Examples of the aromatic ring include an aromatic hydrocarbon group (for example, the number of carbon atoms included in the aromatic ring is from 6 to 20) and an aromatic heterocyclic group (for example, the number of atoms included in the heterocycle is from 5 to 20). The tetravalent organic group represented by X is preferably an aromatic hydrocarbon group. Examples of the aromatic hydrocarbon group include a benzene ring, a naphthalene ring, and a phenanthrene ring.

In a case in which the tetravalent organic group represented by X includes an aromatic ring, such an aromatic ring may have a substituent, or may be unsubstituted. Examples of the substituent in the aromatic ring include an alkyl group, a fluorine atom, an alkyl halide group, a hydroxyl group, and an amino group.

In a case in which the tetravalent organic group represented by X includes a benzene ring, the tetravalent organic group represented by X preferably includes from 1 to 4 benzene rings, more preferably includes from 1 to 3 benzene rings, still more preferably includes one or two benzene rings.

In a case in which the tetravalent organic group represented by X includes two or more benzene rings, each of the benzene rings may be linked by a single bond, or may be linked by a linkage group such as an alkylene group, an alkylene halide group, a carbonyl group, a sulfonyl group, an ether bond (—O—), a sulfide bond (—S—), a silylene bond (—Si(R^{A})₂—; each of two R^{A}s independently represents a hydrogen atom, an alkyl group, or a phenyl group.), or a siloxane bond (—O—(Si(R^{B})₂—O—)ₙ; each of two RBs independently represents a hydrogen atom, an alkyl group, or a phenyl group, and n represents an integer of 1, or 2 or more.), or a composite linkage group in which at least two of such linkage groups are combined. Such two benzene rings may be bound at two positions by at least one of a single bond or a linkage group and thus a five-membered or six-membered ring including such a linkage group may be formed between such two benzene rings.

In Formula (I), a —COOR⁶ group and a —CONH-group are preferably located at the ortho-position to each other, and a —COOR⁷ group and a —CO-group are preferably located at the ortho-position to each other.

Specific examples of the tetravalent organic group represented by X include groups represented by the following Formula (A) to Formula (F). In particular, the tetravalent organic group is preferably a group represented by the following Formula (E), more preferably a group which is represented by the following Formula (E) and in which C contains an ether bond, still more preferably an ether bond from the viewpoint that an underlying layer excellent in flexibility is obtained.

The disclosure is not limited to the following specific examples.

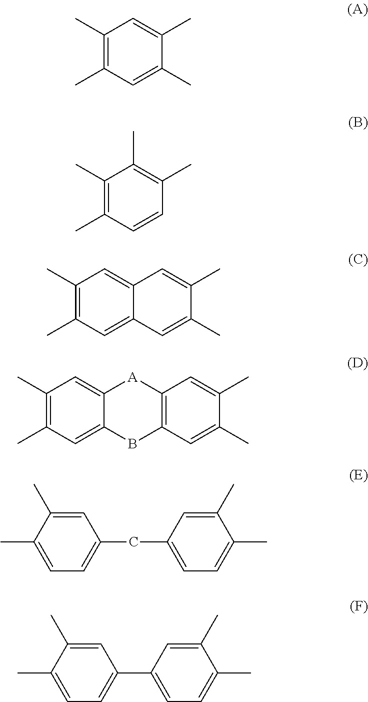

In Formula (D), each of A and B independently represents a single bond or a divalent group not conjugated with a benzene ring. Herein, a case in which both A and B are single bonds does not occur. Examples of the divalent group not conjugated with a benzene ring include a methylene group, a methylene halide group, a methylmethylene halide group, a carbonyl group, a sulfonyl group, an ether bond (—O—), and a sulfide bond (—S—), a silylene bond (—Si(R^{A})₂—; each of two RAs independently represents a hydrogen atom, an alkyl group, or a phenyl group.). In particular, each of A and B independently preferably represents a methylene group, a bis(trifluoromethyl)methylene group, a difluoromethylene group, an ether bond, or a sulfide bond, and an ether bond is more preferred.

In Formula (E), C represents an alkylene group, an alkylene halide group, a carbonyl group, a sulfonyl group, an ether bond (—O—), a sulfide bond (—S—), a phenylene group, an ester bond (—O—C(═O)—), a silylene bond (—Si(R^{A})₂—; each of two R^{A}s independently represents a hydrogen atom, an alkyl group, or a phenyl group.), a siloxane bond (—O—(Si(R^{B})₂—O—)ₙ; each of two R^{B}s independently represents a hydrogen atom, an alkyl group, or a phenyl group, and n represents an integer of 1, or 2 or more.), or a divalent group as a combination of at least two thereof. C preferably includes an ether bond, and is preferably an ether bond.

C may be a structure represented by the following Formula (C1).

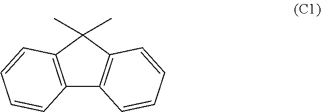

The alkylene group represented by C in Formula (E) is preferably an alkylene group having from 1 to 10 carbon atoms, more preferably an alkylene group having from 1 to 5 carbon atoms, still more preferably an alkylene group having 1 or 2 carbon atoms.

Specific examples of the alkylene group represented by C in Formula (E) include linear alkylene groups such as a methylene group, an ethylene group, a trimethylene group, a tetramethylene group, a pentamethylene group, and a hexamethylene group; and branched alkylene groups such as a methylmethylene group, a methylethylene group, an ethylmethylene group, a dimethylmethylene group, a 1,1-dimethylethylene group, a 1-methyltrimethylene group, a 2-methyltrimethylene group, an ethylethylene group, a 1-methyltetramethylene group, a 2-methyltetramethylene group, a 1-ethyltrimethylene group, a 2-ethyltrimethylene group, a 1,1-dimethyltrimethylene group, a 1,2-dimethyltrimethylene group, a 2,2-dimethyltrimethylene group, a 1-methylpentamethylene group, a 2-methylpentamethylene group, a 3-methylpentamethylene group, a 1-ethyltetramethylene group, a 2-ethyltetramethylene group, a 1,1-dimethyltetramethylene group, a 1,2-dimethyltetramethylene group, a 2,2-dimethyltetramethylene group, a 1,3-dimethyltetramethylene group, a 2,3-dimethyltetramethylene group, and a 1,4-dimethyltetramethylene group. In particular, a methylene group is preferred.

The alkylene halide group represented by C in Formula (E) is preferably an alkylene halide group having from 1 to 10 carbon atoms, more preferably an alkylene halide group having from 1 to 5 carbon atoms, still more preferably an alkylene halide group having from 1 to 3 carbon atoms.

Specific examples of the alkylene halide group represented by C in Formula (E) include an alkylene group in which at least one hydrogen atom included in the alkylene group represented by C in Formula (E) is substituted with a halogen atom such as a fluorine atom or a chlorine atom. In particular, a fluoromethylene group, a difluoromethylene group, or a hexafluorodimethylmethylene group is preferred.

The alkyl group represented by R^{A} or R^{B} included in the silylene bond or the siloxane bond is preferably an alkyl group having from 1 to 5 carbon atoms, more preferably an alkyl group having from 1 to 3 carbon atoms, still more preferably an alkyl group having 1 or 2 carbon atoms. Specific examples of the alkyl group represented by R^{A} or R^{B} include a methyl group, an ethyl group, a n-propyl group, an isopropyl group, a n-butyl group, an isobutyl group, a s-butyl group, and a t-butyl group.

Specific examples of the tetravalent organic group represented by X include groups represented by the following Formula (J) to Formula (O).

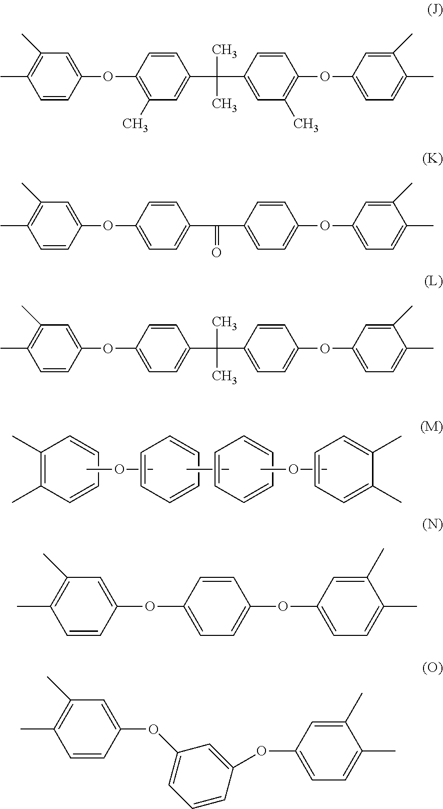

The tetravalent organic group represented by X may include an alicyclic ring from the viewpoint of adjustment of the coefficient of thermal expansion of the underlying layer. In a case in which the tetravalent organic group represented by X includes an alicyclic ring, examples include ring structures each not including an unsaturated bond, such as a cyclopropane ring, a cyclobutane ring, a cyclopentane ring, a cyclohexane ring, a cycloheptane ring, a cyclooctane ring, a decahydronaphthalene ring, a norbornane ring, an adamantane ring, and a bicyclo[2.2.2]octane ring, and ring structures each including an unsaturated bond, such as a cyclohexene ring. Examples also include a spiro ring structure including such a ring structure. The alicyclic ring may have a substituent such as an oxo group (═O), an alkyl group, a fluorine atom, an alkyl halide group, a hydroxyl group, or an amino group, or may be unsubstituted.

Examples of a case in which the tetravalent organic group represented by X has a spiro ring structure include the following Formula (P).

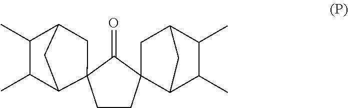

In Formula (I), the number of carbon atoms in the divalent organic group represented by Y is preferably from 4 to 25, more preferably from 6 to 20, still more preferably from 12 to 18.

The backbone of the divalent organic group represented by Y may be the same as the backbone of the tetravalent organic group represented by X, and a preferred backbone of the divalent organic group represented by Y may be the same as a preferred backbone of the tetravalent organic group represented by X. The backbone of the divalent organic group represented by Y may be a structure in which those at two binding positions in the tetravalent organic group represented by X are each replaced with an atom (for example, hydrogen atom) or a functional group (for example, an alkyl group).

The divalent organic group represented by Y may be a divalent aliphatic group or a divalent aromatic group. The divalent organic group represented by Y is preferably a divalent aromatic group from the viewpoint of heat resistance. The divalent aromatic group is, for example, a divalent aromatic hydrocarbon group (for example, the number of atoms included in the aromatic ring is from 6 to 20) or a divalent aromatic heterocyclic group (for example, the number of atoms included in the heterocycle is from 5 to 20), and is preferably a divalent aromatic hydrocarbon group.

The aromatic group refers to a group including an aromatic ring.

Specific examples of the divalent aromatic group represented by Y can include groups represented by the following Formula (G) to the following Formula (H). In particular, a group represented by the following Formula (H) is preferred, a group which is represented by the following Formula (H) and in which D is a group containing a single bond or an ether bond is more preferred, and a single bond or an ether bond is still more preferred from the viewpoint that an underlying layer excellent in flexibility is obtained.

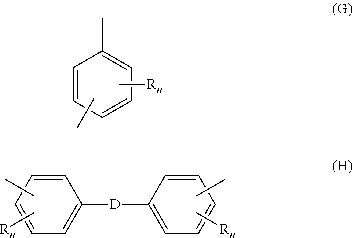

In Formula (G) to Formula (H), each R independently represents an alkyl group, an alkoxy group, a hydroxyl group, an alkyl halide group, a phenyl group, or a halogen atom, and each n independently represents an integer of from 0 to 4.

In Formula (H), D represents a single bond, an alkylene group, an alkylene halide group, a carbonyl group, a sulfonyl group, an ether bond (—O—), a sulfide bond (—S—), a phenylene group, an ester bond (—O—C(═O)—), or a silylene bond (—Si(R^{A})₂—; each of two RAs independently represents a hydrogen atom, an alkyl group, or a phenyl group.), a siloxane bond (—O—(Si(R^{B})₂—O—)ₙ; each of two RBs independently represents a hydrogen atom, an alkyl group, or a phenyl group, and n represents an integer of 1, or 2 or more.), or a divalent group as a combination of at least two thereof. D may be the structure represented by Formula (C1). Specific examples of D in Formula (H) include a single bond, or are the same as specific examples of C in Formula (E).

Each D in Formula (H) is independently preferably a single bond, an ether bond, a group containing an ether bond and a phenylene group, a group containing an ether bond, a phenylene group, and an alkylene group, or the like.

The alkyl group represented by R in Formula (G) to Formula (H) is preferably an alkyl group having from 1 to 10 carbon atoms, more preferably an alkyl group having from 1 to 5 carbon atoms, still more preferably an alkyl group having 1 or 2 carbon atoms.

Specific examples of the alkyl group represented by R in Formula (G) to Formula (H) include a methyl group, an ethyl group, a n-propyl group, an isopropyl group, a n-butyl group, an isobutyl group, a s-butyl group, and a t-butyl group.

The alkoxy group represented by R in Formula (G) to Formula (H) is preferably an alkoxy group having from 1 to 10 carbon atoms, more preferably an alkoxy group having from 1 to 5 carbon atoms, still more preferably an alkoxy group having 1 or 2 carbon atoms.

Specific examples of the alkoxy group represented by R in Formula (G) to Formula (H) include a methoxy group, an ethoxy group, a n-propoxy group, an isopropoxy group, a n-butoxy group, an isobutoxy group, a s-butoxy group, and a t-butoxy group.

The alkyl halide group represented by R in Formula (G) to Formula (H) is preferably an alkyl halide group having from 1 to 5 carbon atoms, more preferably an alkyl halide group having from 1 to 3 carbon atoms, still more preferably an alkyl halide group having 1 or 2 carbon atoms.

Specific examples of the alkyl halide group represented by R in Formula (G) to Formula (H) include an alkyl group in which at least one hydrogen atom contained in the alkyl group represented by R in Formula (G) to Formula (H) is substituted with a halogen atom such as a fluorine atom or a chlorine atom. In particular, a fluoromethyl group, a difluoromethyl group, or a trifluoromethyl group is preferred.

Each n in Formula (G) to Formula (H) independently represents preferably from 0 to 2, more preferably 0 or 1, still more preferably 0.

Specific examples of the divalent aliphatic group represented by Y include a linear or branched alkylene group, a cycloalkylene group, and a divalent group having a polyalkylene oxide structure.

The linear or branched alkylene group represented by Y is preferably an alkylene group having from 1 to 20 carbon atoms, more preferably an alkylene group having from 1 to 15 carbon atoms, still more preferably an alkylene group having from 1 to 10 carbon atoms.

Specific examples of the alkylene group represented by Y include a tetramethylene group, a hexamethylene group, a heptamethylene group, an octamethylene group, a nonamethylene group, a decamethylene group, an undecamethylene group, a dodecamethylene group, a 2-methylpentamethylene group, a 2-methylhexamethylene group, a 2-methylheptamethylene group, a 2-methyloctamethylene group, a 2-methylnonamethylene group, and a 2-methyldecamethylene group.

The cycloalkylene group represented by Y is preferably a cycloalkylene group having from 3 to 10 carbon atoms, more preferably a cycloalkylene group having from 3 to 6 carbon atoms.

Specific examples of the cycloalkylene group represented by Y include a cyclopropylene group and a cyclohexylene group.

The unit structure contained in the divalent group having the polyalkylene oxide structure represented by Y is preferably an alkylene oxide structure having from 1 to 10 carbon atoms, more preferably an alkylene oxide structure having from 1 to 8 carbon atoms, still more preferably an alkylene oxide structure having from 1 to 4 carbon atoms. In particular, the polyalkylene oxide structure is preferably a polyethylene oxide structure or a polypropylene oxide structure. The alkylene group in the alkylene oxide structure may be linear or branched. The unit structure in the polyalkylene oxide structure may be in the form of one kind thereof, or two or more kinds thereof.

The divalent organic group represented by Y may be a divalent group having a polysiloxane structure. Examples of the divalent group having a polysiloxane structure represented by Y include a divalent group having a polysiloxane structure, in which a silicon atom in the polysiloxane structure is bound with a hydrogen atom, an alkyl group having from 1 to 20 carbon atoms, or an aryl group having from 6 to 18 carbon atoms.

Specific examples of the alkyl group having from 1 to 20 carbon atoms, bound with a silicon atom in the polysiloxane structure, include a methyl group, an ethyl group, a n-propyl group, an isopropyl group, a n-butyl group, a t-butyl group, a n-octyl group, a 2-ethylhexyl group, and a n-dodecyl group. In particular, a methyl group is preferred.

The aryl group having from 6 to 18 carbon atoms, bound with a silicon atom in the polysiloxane structure, may be unsubstituted or substituted with a substituent. Specific examples of the substituent in a case in which the aryl group has a substituent include a halogen atom, an alkoxy group, and a hydroxy group. Specific examples of the aryl group having from 6 to 18 carbon atoms include a phenyl group, a naphthyl group, and a benzyl group. In particular, a phenyl group is preferred.

The alkyl group having from 1 to 20 carbon atoms or the aryl group having from 6 to 18 carbon atoms in the polysiloxane structure may be in the form of one kind thereof, or two or more kinds thereof.

A silicon atom contained in the divalent group having a polysiloxane structure represented by Y may be bound with an NH group in Formula (I) via an alkylene group such as a methylene group or an ethylene group, an arylene group such as a phenylene group, or the like.

The group represented by Formula (G) is preferably a group represented by the following Formula (G′), and the group represented by Formula (H) is preferably a group represented by the following Formula (H′), Formula (H″), or Formula (H″′).

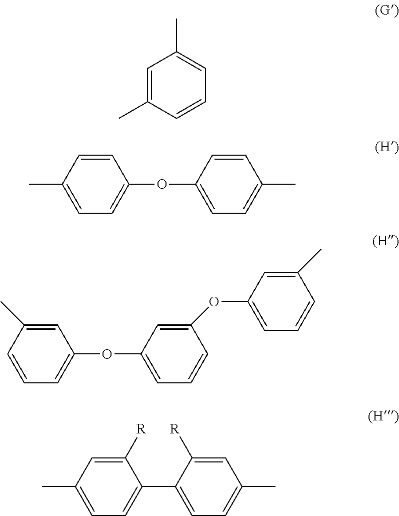

In Formula (H″′) each R independently represents an alkyl group, an alkoxy group, an alkyl halide group, a phenyl group, a hydroxyl group, or a halogen atom. R is preferably an alkyl group, more preferably a methyl group.

A combination of the tetravalent organic group represented by X and the divalent organic group represented by Y in Formula (I) is not particularly limited. Examples of the combination of the tetravalent organic group represented by X and the divalent organic group represented by Y include a combination in which X is the group represented by Formula (E) and Y is the group represented by Formula (H).

Each of R⁶ and R⁷ independently represents a hydrogen atom or a monovalent organic group. Examples of the monovalent organic group include an aliphatic hydrocarbon group having from 1 to 4 carbon atoms and an organic group having an unsaturated double bond.

Specific examples of the aliphatic hydrocarbon group having from 1 to 4 carbon atoms include a methyl group, an ethyl group, a n-propyl group, an isopropyl group, a n-butyl group, and a t-butyl group, and in particular, an ethyl group, an isobutyl group, or a t-butyl group is preferred.

The content rate of the structural unit represented by Formula (I) included in the compound having the structural unit represented by Formula (I) is preferably 60% by mol or more, more preferably 70% by mol or more, still more preferably 80% by mol or more with respect to the whole structural unit. The upper limit of the content rate is not particularly limited, and may be 100% by mol.

The polyimide precursor may be one synthesized with a tetracarboxylic dianhydride and a diamine compound. In this case, in Formula (I), X corresponds to a tetracarboxylic dianhydride-derived residue and Y corresponds to a diamine compound-derived residue. The polyimide precursor may be one synthesized with tetracarboxylic acid instead of the tetracarboxylic dianhydride.

Specific examples of the tetracarboxylic dianhydride include pyromellitic dianhydride, 2,3,6,7-naphthalenetetracarboxylic dianhydride, 3,3′,4,4′-biphenyltetracarboxylic dianhydride, 3,3′,4,4′-biphenyl ethertetracarboxylic dianhydride, 3,3′,4,4′-benzophenonetetracarboxylic dianhydride, 1,2,5,6-naphthalenetetracarboxylic dianhydride, 2,3,5,6-pyridinetetracarboxylic dianhydride, 1,4,5,8-naphthalenetetracarboxylic dianhydride, 3,4,9,10-perylenetetracarboxylic dianhydride, m-terphenyl-3,3′,4,4′-tetracarboxylic dianhydride, p-terphenyl-3,3′,4,4′-tetracarboxylic dianhydride, 1,1,1,3,3,3-hexafluoro-2,2-bis(2,3-dicarboxyphenyl)propane dianhydride, 1,1,1,3,3,3-hexafluoro-2,2-bis(3,4-dicarboxyphenyl)propane dianhydride, 2,2-bis(2,3-dicarboxyphenyl)propane dianhydride, 2,2-bis(3,4-dicarboxyphenyl)propane dianhydride, 2,2-bis{4′-(2,3-dicarboxyphenoxy)phenyl}propane dianhydride, 2,2-bis{4′-(3,4-dicarboxyphenoxy)phenyl}propane dianhydride, 1,1,1,3,3,3-hexafluoro-2,2-bis{4′-(2,3-dicarboxyphenoxy)phenyl}propane dianhydride, 1,1,1,3,3,3-hexafluoro-2,2-bis{4′-(3,4-dicarboxyphenoxy)phenyl}propane dianhydride, 4,4′-oxydiphthalic dianhydride, 4,4′-sulfonyldiphthalic dianhydride, and 9,9-bis(3,4-dicarboxyphenyl)fluorene dianhydride.

The tetracarboxylic dianhydride may be used singly, or in combination of two or more kinds thereof.

Specific examples of the diamine compound include 2,2′-dimethylbiphenyl-4,4′-diamine, 2,2′-bis(trifluoromethyl)-4,4′-diaminobiphenyl, 2,2′-difluoro-4,4′-diaminobiphenyl, p-phenylenediamine, m-phenylenediamine, p-xylylenediamine, m-xylylenediamine, 1,5-diaminonaphthalene, benzidine, 4,4′-diaminodiphenyl ether, 3,4′-diaminodiphenyl ether, 3,3′-diaminodiphenyl ether, 2,4′-diaminodiphenyl ether, 2,2′-diaminodiphenyl ether, 4,4′-diaminodiphenylsulfone, 3,4′-diaminodiphenylsulfone, 3,3′-diaminodiphenylsulfone, 2,4′-diaminodiphenylsulfone, 2,2′-diaminodiphenylsulfone, 4,4′-diaminodiphenyl sulfide, 3,4′-diaminodiphenyl sulfide, 3,3′-diaminodiphenyl sulfide, 2,4′-diaminodiphenyl sulfide, 2,2′-diaminodiphenyl sulfide, o-tolidine, o-tolidinesulfone, 4,4′-methylenebis(2,6-diethylaniline), 4,4′-methylenebis(2,6-diisopropylaniline), 2,4-diaminomesitylene, 1,5-diaminonaphthalene, 4,4′-benzophenonediamine, bis-{4-(4′-aminophenoxy)phenyl}sulfone, 2,2-bis{4-(4′-aminophenoxy)phenyl}propane, 3,3′-dimethyl-4,4′-diaminodiphenylmethane, 3,3′,5,5′-tetramethyl-4,4′-diaminodiphenylmethane, bis{4-(3′-aminophenoxy)phenyl}sulfone, 2,2-bis(4-aminophenyl)propane, 9,9-bis(4-aminophenyl)fluorene, 1,3-bis(3-aminophenoxy)benzene, 1,4-diaminobutane, 1,6-diaminohexane, 1,7-diaminoheptane, 1,8-diaminooctane, 1,9-diaminononane, 1,10-diaminodecane, 1,11-diaminoundecane, 1,12-diaminododecane, 2-methyl-1,5-diaminopentane, 2-methyl-1,6-diaminohexane, 2-methyl-1,7-diaminoheptane, 2-methyl-1,8-diaminooctane, 2-methyl-1,9-diaminononane, 2-methyl-1,10-diaminodecane, 1,4-cyclohexanediamine, 1,3-cyclohexanediamine, and diaminopolysiloxane.

The diamine compound may be used singly, or in combination of two or more kinds thereof.

The compound which has the structural unit represented by Formula (I) and in which at least one of R⁶ or R⁷ in Formula (I) is a monovalent organic group can be obtained by, for example, the following (a) or (b) method.
(a) A method including reacting a tetracarboxylic dianhydride (preferably, a tetracarboxylic dianhydride represented by the following Formula (I′)) and a compound represented by R—OH in an organic solvent to provide a diester derivative, and then condensation-reacting the diester derivative and a diamine compound represented by H₂N—Y—NH₂.
(b) A method including reacting a tetracarboxylic dianhydride and a diamine compound represented by H₂N—Y—NH₂ in an organic solvent to obtain a polyamide acid solution, and adding a compound represented by R—OH to the polyamide acid solution to perform a reaction in an organic solvent, thereby introducing an ester group.

Y in the diamine compound represented by H₂N—Y—NH₂ is the same as Y in Formula (I), and also specific examples and preferred examples thereof are also the same as those of Y in Formula (I). R in the compound represented by R—OH represents a monovalent organic group, and specific examples and preferred examples thereof are the same as in the case of R⁶ and R⁷ in Formula (I).

Each of the tetracarboxylic dianhydride represented by Formula (I′), the diamine compound represented by H₂N—Y—NH₂, and the compound represented by R—OH may be used singly, or in combination of two or more kinds thereof.

Examples of the organic solvent include N-methyl-2-pyrrolidone, γ-butyrolactone, dimethoxyimidazolidinone, and 3-methoxy-N,N-dimethylpropionamide, and in particular, 3-methoxy-N,N-dimethylpropionamide is preferred.

The polyimide precursor may also be synthesized by allowing not only the compound represented by R—OH, but also a dehydration-condensation agent to act on a polyamide acid solution. The dehydration-condensation agent preferably includes at least one selected from the group consisting of trifluoroacetic anhydride, N,N′-dicyclohexylcarbodiimide (DCC), and 1,3-diisopropylcarbodiimide (DIC).

The above compound included in the polyimide precursor can be obtained by allowing the compound represented by R—OH to act on a tetracarboxylic dianhydride represented by the following Formula (I′) to provide a diester derivative, then allowing a chlorinating agent such as thionyl chloride to act on the derivative, to perform conversion to an acid chloride, and then reacting the diamine compound represented by H₂N—Y—NH₂ and the acid chloride.

The above compound included in the polyimide precursor can be obtained by allowing the compound represented by R—OH to act on a tetracarboxylic dianhydride represented by the following Formula (I′) to provide a diester derivative, and then reacting the diamine compound represented by H₂N—Y—NH₂ and the diester derivative in the presence of a carbodiimide compound.

The above compound included in the polyimide precursor can be obtained by reacting a tetracarboxylic dianhydride represented by the following Formula (I′) and the diamine compound represented by H₂N—Y—NH₂ to provide a polyamide acid, then converting the polyamide acid to an isoimidated product in the presence of a dehydration-condensation agent such as trifluoroacetic anhydride, and then allowing the compound represented by R—OH to act on the isoimidated product. Alternatively, the above compound may also be obtained by allowing the compound represented by R—OH to act on one portion of the tetracarboxylic dianhydride in advance to provide a partially esterified tetracarboxylic dianhydride, and reacting the tetracarboxylic dianhydride and the diamine compound represented by H₂N—Y—NH₂.

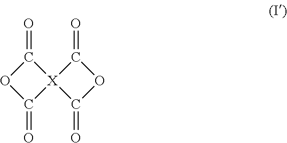

X in Formula (I′) is the same as X in Formula (I), and specific examples and preferred examples thereof are also the same as those of X in Formula (I).

Examples of the compound represented by R—OH used for synthesis of the above compound included in the polyimide precursor include methanol, ethanol, n-propanol, isopropanol, n-butanol, 2-hydroxyethyl acrylate, 2-hydroxyethyl methacrylate, 2-hydroxypropyl acrylate, 2-hydroxypropyl methacrylate, 2-hydroxybutyl acrylate, 2-hydroxybutyl methacrylate, 4-hydroxybutyl acrylate, and 4-hydroxybutyl methacrylate.

### —Polybenzoxazole Precursor—

The type of the polybenzoxazole precursor is not particularly limited. The polybenzoxazole precursor preferably optionally has a structural unit represented by the following Formula (II).

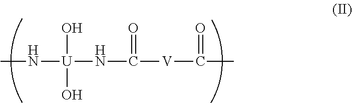

In Formula (II), U is a tetravalent organic group, and V is a divalent organic group.

The hydroxy group-containing amide unit in Formula (II) is partially converted into an oxazole ring excellent in heat resistance, chemical resistance, and electric characteristics, by dehydration/ring-closing in a heating step.

The hydroxy group-containing amide unit in the structural unit represented by Formula (II) has an effect of enhancing solubility of a polymer in an aqueous alkali solution.

A polymer having the structural unit represented by Formula (II) may contain only one of the structural units, or two or more kinds of such structural units. In the case of a copolymer having two or more kinds of such structural units, the polymer may be a polymer having at least two kinds of such structural units represented by Formula (II), or a polymer having a structure represented by Formula (III).

In a case in which the polymer having the structural unit represented by Formula (II) has two or more kinds of such structural units represented by Formula (II), a combination of such structural units represented by Formula (II) is not particularly limited, and may be, for example, a combination of a structural unit in which the divalent organic group represented by V is a divalent aromatic group and a structural unit in which V is a divalent organic group having an aliphatic structure having from 6 to 30 carbon atoms.

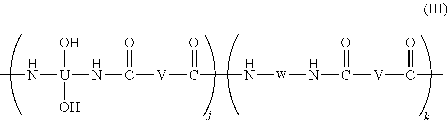

In Formula (III), U is a tetravalent organic group, and each of V and W is independently a divalent organic group. j and k are each a molar fraction, the sum of j and k is 100% by mol, j is from 60 to 99.9% by mol, k is from 0.1% by mol to 40% by mol (preferably j is from 80% by mol to 99.9% by mol, and k is from 0.1% by mol to 20% by mol).

In Formulae (II) and (III), the tetravalent organic group represented by U is a residue of the diamine compound used in the synthesis of polyhydroxyamide. The tetravalent organic group represented by U is preferably a tetravalent aromatic group, or an organic group having from 6 to 40 carbon atoms, more preferably a tetravalent aromatic group having from 6 to 40 carbon atoms. The tetravalent aromatic group is preferably one in which all of four binding moieties are present on an aromatic ring.

Examples of the diamine compound providing the tetravalent organic group represented by U include 3,3′-diamino-4,4′-dihydroxybiphenyl, 4,4′-diamino-3,3′-dihydroxybiphenyl, bis(3-amino-4-hydroxyphenyl)propane, bis(4-amino-3-hydroxyphenyl)propane, bis(3-amino-4-hydroxyphenyl)sulfone, bis(4-amino-3-hydroxyphenyl)sulfone, 2,2-bis(3-amino-4-hydroxyphenyl)-1,1,1,3,3,3-hexafluoropropane, and 2,2-bis(4-amino-3-hydroxyphenyl)-1,1,1,3,3,3-hexafluoropropane, but not limited thereto.

The divalent organic group represented by W in Formula (III) is a residue of the diamine compound used in the synthesis of polyhydroxyamide. The divalent organic group represented by W is preferably a divalent aromatic group, a divalent aliphatic group, or an organic group having from 4 to 20 carbon atoms, more preferably an aromatic group having from 4 to 20 carbon atoms. The divalent organic group represented by W is a residue of any other diamine compound than the tetravalent organic group represented by U.

Examples of the diamine compound providing the divalent organic group represented by W include aromatic diamine compounds such as 4,4′-diaminodiphenyl ether, 4,4′-diaminodiphenylmethane, 4,4′-diaminodiphenylsulfone, 4,4′-diaminodiphenyl sulfide, benzidine, m-phenylenediamine, p-phenylenediamine, 1,5-naphthalenediamine, 2,6-naphthalenediamine, bis(4-aminophenoxyphenyl)sulfone, bis(3-aminophenoxyphenyl)sulfone, bis(4-aminophenoxy)biphenyl, bis[4-(4-aminophenoxy)phenyl]ether, and 1,4-bis(4-aminophenoxy)benzene. Examples of a diamine compound having a silicone group include LP-7100, X-22-161AS, X-22-161A, X-22-161B, X-22-161C, and X-22-161E (trade names, all are manufactured by Shin-Etsu Chemical Co., Ltd.), but not limited thereto.

In Formulae (II) and (III), the divalent organic group represented by Vis a dicarboxylic acid used in the synthesis of polyhydroxyamide, or a residue of a dicarboxylic acid derivative (hereinafter, referred to as “dicarboxylic acid compound”). The divalent organic group represented by V is preferably a divalent aromatic group, or an organic group having from 6 to 40 carbon atoms.

A divalent aromatic group having from 6 to 40 is preferred from the viewpoint of heat resistance, and the divalent aromatic group is preferably one in which all of two or more binding moieties are present on the aromatic ring.

V is preferably a divalent organic group having an aliphatic structure having from 6 to 30 carbon atoms from the viewpoint that the percentage of dehydration/ring-closing is high in a heating step at a low temperature (for example, 200° C. or less) and favorable heat resistance and mechanical strength are exhibited.

Examples of the dicarboxylic acid providing the divalent organic group represented by V include aromatic dicarboxylic acids such as isophthalic acid, terephthalic acid, 2,2-bis(4-carboxyphenyl)-1,1,1,3,3,3-hexafluoropropane, 4,4′-dicarboxybiphenyl, 4,4′-dicarboxydiphenyl ether(4,4′-diphenyl ether dicarboxylic acid), 4,4′-dicarboxytetraphenylsilane, bis(4-carboxyphenyl)sulfone, 2,2-bis(p-carboxyphenyl)propane, 5-tert-butylisophthalic acid, 5-bromoisophthalic acid, 5-fluoroisophthalic acid, 5-chloroisophthalic acid, and 2,6-naphthalenedicarboxylic acid, 1,2-cyclobutanedicarboxylic acid, 1,4-cyclohexanedicarboxylic acid, 1,3-cyclopentanedicarboxylic acid, and those each having an aliphatic linear structure, such as malonic acid, dimethylmalonic acid, ethylmalonic acid, isopropylmalonic acid, di-n-butylmalonic acid, succinic acid, tetrafluorosuccinic acid, methylsuccinic acid, 2,2-dimethylsuccinic acid, 2,3-dimethylsuccinic acid, dimethylmethylsuccinic acid, glutaric acid, hexafluoroglutaric acid, 2-methylglutaric acid, 3-methylglutaric acid, 2,2-dimethylglutaric acid, 3,3-dimethylglutaric acid, 3-ethyl-3-methylglutaric acid, adipic acid, octafluoroadipic acid, 3-methyladipic acid, pimelic acid, 2,2,6,6-tetramethylpimelic acid, suberic acid, dodecafluorosuberic acid, azelaic acid, sebacic acid, hexadecafluorosebacic acid, 1,9-nonanedioic acid, dodecanedioic acid, tridecanedioic acid, tetradecanedioic acid, pentadecanedioic acid, hexadecanedioic acid, heptadecanedioic acid, octadecanedioic acid, nonadecanedioic acid, eicosanedioic acid, heneicosanedioic acid, docosanedioic acid, tricosanedioic acid, tetracosanedioic acid, pentacosanedioic acid, hexacosanedioic acid, heptacosanedioic acid, octacosanedioic acid, nonacosanedioic acid, triacontanedioic acid, hentriacontanedioic acid, dotriacontanedioic acid, and diglycolic acid, and further include dicarboxylic acids represented by the following Formulae, but not limited thereto. Such compounds may be used singly, or in combination of two or more kinds thereof.

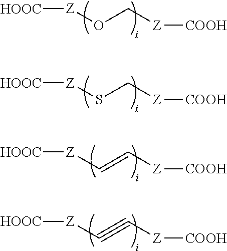

In Formulae, each Z is independently a hydrocarbon group having from 1 to 6, and i is an integer of from 1 to 6.

In the disclosure, the method of producing the polybenzoxazole precursor is not particularly limited. In general, the polybenzoxazole precursor can be synthesized with a dicarboxylic acid compound, a hydroxy group-containing diamine compound, and, if necessary, a diamine compound other than such a hydroxy group-containing diamine compound. Specifically, the polybenzoxazole precursor can be synthesized by converting a dicarboxylic acid derivative into a dihalide derivative and then reacting the dihalide derivative with a diamine compound. The dihalide derivative is preferably a dichloride derivative.

The method of synthesizing the dichloride derivative can be a method including reacting a dicarboxylic acid compound and a halogenating agent in a solvent, or performing a reaction in an excess halogenating agent and then distilling off an excess content. The halogenating agent used here can be thionyl chloride, phosphoryl chloride, phosphorus oxychloride, phosphorus pentachloride, or the like used in a common acid chloride formation reaction of a carboxylic acid. The reaction solvent used here can be, for example, N-methyl-2-pyrrolidone, N-methyl-2-pyridone, N,N-dimethylacetamide, N,N-dimethylformamide, toluene, or benzene.

The amount of use of such a halogenating agent, with respect to 1.0 mol of the dicarboxylic acid derivative, is preferably from 1.5 mol to 3.0 mol, more preferably from 1.7 mol to 2.5 mol in the case of the reaction in the solvent, or is preferably from 4.0 mol to 50 mol, more preferably from 5.0 mol to 20 mol in the case of the reaction in the halogenating agent. The reaction temperature is preferably from −10° C. to 70° C., more preferably from 0° C. to 20° C.

The reaction of the dichloride derivative and the diamine compound is preferably performed in an organic solvent in the presence of a dehydrohalogenating agent. The dehydrohalogenating agent used here can be an organic base such as pyridine or triethylamine. The organic solvent used here can be N-methyl-2-pyrrolidone, N-methyl-2-pyridone, N,N-dimethylacetamide, N,N-dimethylformamide, or the like. The reaction temperature is preferably from −10° C. to 30° C., more preferably from 0° C. to 20° C.

### ((B) Thermosetting Resin)

The positive photosensitive resin composition preferably includes (B) a thermosetting resin. Examples of the (B) thermosetting resin include an acrylate resin, an epoxy resin, a cyanate ester resin, a maleimide resin, an allylnadic imide resin, a phenol resin, a urea resin, a melamine resin, an alkyd resin, an unsaturated polyester resin, a diallyl phthalate resin, a silicone resin, a resorcinol-formaldehyde resin, a triallyl cyanurate resin, a polyisocyanate resin, a resin containing tris(2-hydroxyethyl)isocyanurate, a resin containing triallyl trimethacrylate, and a thermosetting resin synthesized from cyclopentadiene.

A glycidyl group-containing compound can be blended in the positive photosensitive resin composition, and thus reacted with the component (A) to form a crosslinked structure during heating and curing of the curable resin composition layer after pattern formation. Thus, a film can be prevented from being brittle or being melted. The compound having a glycidyl group, used here, can be conventionally known one. Specific examples thereof include a bisphenol A epoxy resin, a bisphenol F epoxy resin, a phenol/novolac/epoxy resin, a cresol/novolac/epoxy resin, an alicyclic epoxy resin, glycidylamine, heterocyclic epoxy, or polyalkylene glycol diglycidyl ether.

In a case in which such a compound having a glycidyl group is blended, the amount of blending thereof is preferably from 1 part by mass to 30 parts by mass, more preferably from 3 parts by mass to 25 parts by mass with respect to 100 parts by mass of the component (A) from the viewpoint of solubility in an aqueous alkali solution and physical properties of a cured film.

### ((C) Photosensitizer)

The positive photosensitive resin composition preferably includes (C) a photosensitizer. The (C) photosensitizer used here can be, for example, a photo-acid generator that generates an acid by light irradiation.

The photo-acid generator has the function of generating an acid by light irradiation to increase the solubility of a portion irradiated with light, of the curable resin composition layer, in an aqueous alkali solution.

Examples of the photo-acid generator include an o-quinonediazide compound, an aryldiazonium salt, a diaryliodonium salt, and a triarylsulfonium salt. Such photo-acid generators may be used singly, or in combination of two or more kinds thereof depending on the object, the intended use, or the like. In particular, an o-quinonediazide compound is preferably used because it has high sensitivity.

The o-quinonediazide compound used here can be, for example, one obtained by a condensation reaction of o-quinonediazidesulfonium chloride and, for example, a hydroxy compound and/or an amino compound in the presence of a base removal agent.

Examples of the o-quinonediazidesulfonium chloride used in the reaction include benzoquinone-1,2-diazide-4-sulfonium chloride, naphthoquinone-1,2-diazide-5-sulfonyl chloride, and naphthoquinone-1,2-diazide-6-sulfonyl chloride.

Examples of the hydroxy compound used in the reaction include hydroquinone, resorcinol, pyrogallol, bisphenolA, bis(4-hydroxyphenyl)methane, 1,1-bis(4-hydroxyphenyl)-1-[4-{1-(4-hydroxyphenyl)-1-methylethyl}phenyl]ethane, 2,2-bis(4-hydroxyphenyl)hexafluoropropane, 2,3,4-trihydroxybenzophenone, 2,3,4,4′-tetrahydroxybenzophenone, 2,2′,4,4′-tetrahydroxybenzophenone, 2,3,4,2′,3′-pentahydroxybenzophenone, 2,3,4,3′,4′,5′-hexahydroxybenzophenone, bis(2,3,4-trihydroxyphenyl)methane, bis(2,3,4-trihydroxyphenyl)propane, 4b,5,9b,10-tetrahydro-1,3,6,8-tetrahydroxy-5,10-dimethylindeno[2,1-a]indene, tris(4-hydroxyphenyl)methane, and tris(4-hydroxyphenyl)ethane.

Examples of the amino compound used in the reaction include p-phenylenediamine, m-phenylenediamine, 4,4′-diaminodiphenyl ether, 4,4′-diaminodiphenylmethane, 4,4′-diaminodiphenylsulfone, 4,4′-diaminodiphenyl sulfide, o-aminophenol, m-aminophenol, p-aminophenol, 3,3′-diamino-4,4′-dihydroxybiphenyl, 4,4′-diamino-3,3′-dihydroxybiphenyl, bis(3-amino-4-hydroxyphenyl)propane, bis(4-amino-3-hydroxyphenyl)propane, bis(3-amino-4-hydroxyphenyl)sulfone, bis(4-amino-3-hydroxyphenyl)sulfone, bis(3-amino-4-hydroxyphenyl)hexafluoropropane, and bis(4-amino-3-hydroxyphenyl)hexafluoropropane.

In particular, one obtained by a condensation reaction of 1,1-bis(4-hydroxyphenyl)-1-[4-{1-(4-hydroxyphenyl)-1-methylethyl}phenyl]ethane and 1-naphthoquinone-2-diazide-5-sulfonyl chloride, or one obtained by a condensation reaction of tris(4-hydroxyphenyl)methane or tris(4-hydroxyphenyl)ethane and 1-naphthoquinone-2-diazide-5-sulfonyl chloride is preferably used from the viewpoint of reactivity during synthesize of the o-quinonediazide compound and from the viewpoint of an appropriate absorption wavelength range during exposure of the curable resin composition layer.

Examples of the dehydrochlorinating agent used in the reaction include sodium carbonate, sodium hydroxide, sodium hydrogen carbonate, potassium carbonate, potassium hydroxide, trimethylamine, triethylamine, and pyridine. The reaction solvent used here is, for example, dioxane, acetone, methyl ethyl ketone, tetrahydrofuran, diethyl ether, or N-methyl-2-pyrrolidone.

Blending of o-quinonediazide sulfonyl chloride and the hydroxy compound and/or the amino compound is preferably made so that the total molar number of a hydroxy group and an amino group is from 0.5 to 1 mol with respect to 1 mol of the o-quinonediazide sulfonyl chloride. The blending proportion of the dehydrochlorinating agent and the o-quinonediazide sulfonyl chloride is in a range of from 0.95/1 to 1/0.95 molar equivalents.

In the above reaction, a preferred reaction temperature is from 0° C. to 40° C. and a preferred reaction time is from 1 hour to 10 hours.

The content of the (C) photosensitizer is preferably from 3 parts by mass to 100 parts by mass, more preferably from 5 parts by mass to 30 parts by mass, still more preferably from 5 parts by mass to 20 parts by mass with respect to 100 parts by mass of the (A) alkali-soluble resin from the viewpoint that the difference in rate of dissolution between an exposed area and an unexposed area is larger to result in a more improvement in sensitivity.

### (Low-Molecular Compound Having Phenolic Hydroxyl Group)

The positive photosensitive resin composition can include a low-molecular compound having a phenolic hydroxyl group.

The low-molecular compound having a phenolic hydroxyl group is used for increasing the rate of dissolution of an exposed area during development with an aqueous alkali solution, resulting in an enhancement in sensitivity. Such a component is contained and thus such a component is reacted with the component (A) to form a crosslinked structure during heating and curing of the curable resin composition layer after pattern formation. Thus, a film can be prevented from being brittle, being melted, or the like.

The molecular weight of the low-molecular compound having a phenolic hydroxyl group is preferably 2000 or less. The molecular weight is preferably from 94 to 2000, more preferably from 108 to 2000, still more preferably from 108 to 1500 in terms of the number average molecular weight, in consideration of solubility in an aqueous alkali solution and the balance between photosensitive properties and physical properties of a cured film.

The amount of blending of the low-molecular compound having a phenolic hydroxyl group is preferably from 1 part by mass to 50 parts by mass, more preferably from 2 parts by mass to 30 parts by mass, still more preferably from 3 parts by mass to 25 parts by mass with respect to 100 parts by mass of the component (A) from the viewpoint of the development time, an acceptable margin of the percentage of the remaining film on an unexposed area, and properties of a cured film.

(Compound that Generates Acid by Heating)

The positive photosensitive resin composition can include a compound that generates an acid by heating.

This component can be used to allow for generation of an acid during heating of the curable resin composition layer, and a reaction of the component (A) with the glycidyl group-containing compound and the low-molecular compound having a phenolic hydroxyl group, namely, a thermal crosslinking reaction is promoted and heat resistance of a cured film is enhanced. This component also generates an acid by light irradiation, and therefore the solubility of an exposed area in an aqueous alkali solution increases. Accordingly, the difference in solubility in an aqueous alkali solution between an unexposed area and an exposed area is further larger to result in an enhancement in resolution.

Such a component is preferably, for example, one that generate an acid by heating to from 50° C. to 250° C. Specific examples of such a component include a salt formed from a strong acid and a base, such as an onium salt, and imide sulfonate.

Examples of the onium salt include diaryliodonium salts such as an aryldiazonium salt and a diphenyliodonium salt; di(alkylaryl)iodonium salts such as a di(t-butylphenyl)iodonium salt; trialkylsulfonium salts such as a trimethylsulfonium salt; dialkylmonoarylsulfonium salts such as a dimethylphenylsulfonium salt; diarylmonoalkylsulfonium salts such as a diphenylmethylsulfonium salt; and triarylsulfonium salts. In particular, a di(t-butylphenyl)iodonium salt of p-toluenesulfonic acid, a di(t-butylphenyl)iodonium salt of trifluoromethanesulfonic acid, a trimethylsulfonium salt of trifluoromethanesulfonic acid, a dimethylphenylsulfonium salt of trifluoromethanesulfonic acid, a diphenylmethylsulfonium salt of trifluoromethanesulfonic acid, a di(t-butylphenyl)iodonium salt of nonafluorobutanesulfonic acid, a diphenyliodonium salt of camphorsulfonic acid, a diphenyliodonium salt of ethanesulfonic acid, a dimethylphenylsulfonium salt of benzenesulfonic acid, or a diphenylmethylsulfonium salt of toluenesulfonic acid is preferred.

The salt formed from a strong acid and a base, here used, can be not only the above onium salt, but also the following salt formed from a strong acid and a base, for example, a pyridinium salt. Examples of a strong acid include arylsulfonic acids such as p-toluenesulfonic acid and benzenesulfonic acid, camphorsulfonic acid, perfluoroalkylsulfonic acids such as trifluoromethanesulfonic acid and nonafluorobutanesulfonic acid, and alkylsulfonic acids such as methanesulfonic acid, ethanesulfonic acid, and butanesulfonic acid. Examples of the base include pyridine, alkylpyridines such as 2,4,6-trimethylpyridine, N-alkylpyridines such as 2-chloro-N-methylpyridine, and halogenated-N-alkylpyridines.

The imide sulfonate used here can be naphthoylimide sulfonate or phthalimide sulfonate.

The amount of blending of this component is preferably from 0.1 parts by mass to 30 parts by mass, more preferably from 0.2 parts by mass to 20 parts by mass, still more preferably from 0.5 parts by mass to 10 parts by mass with respect to 100 parts by mass of the component (A).

### (Elastomer)

The positive photosensitive resin composition may contain an elastomer component, in addition to those described above.

The elastomer is used for imparting flexibility to a cured product of the positive photosensitive resin composition. The elastomer used here can be conventionally known one, and the polymer included in the elastomer preferably has a Tg of 20° C. or less.

Examples of such an elastomer include a styrene-based elastomer, an olefin-based elastomer, a urethane-based elastomer, a polyester-based elastomer, a polyamide-based elastomer, an acrylic elastomer, and a silicone-based elastomer. These may be used singly, or in combination of two or more kinds thereof.

The amount of blending of the elastomer is preferably from 1 part by mass to 50 parts by mass, more preferably from 5 parts by mass to 30 parts by mass with respect to 100 parts by mass of the component (A).

### (Other Components)

The positive photosensitive resin composition may further contain, in addition to the above, component(s) such as a dissolution promoter, a dissolution inhibitor, a coupling agent, a surfactant, and/or a leveling agent. The positive photosensitive resin composition may further contain an inorganic particle such as silica, alumina, or boron nitride, an olefin particle such as ethylene particle or propylene particle, an organic particle such as a (meth)acrylic particle, and/or the like.

### (Solvent)

The positive photosensitive resin composition may further include a solvent for dissolution/dispersion of the above components.

Specific examples of the solvent include γ-butyrolactone, ethyl lactate, propylene glycol monomethyl ether acetate, benzyl acetate, n-butyl acetate, ethoxyethyl propionate, 3-methylmethoxy propionate, N-methyl-2-pyrrolidone, N,N-dimethylformamide, N,N-dimethylacetamide, dimethylsulfoxide, hexamethylphosphoramide, tetramethylenesulfone, diethylketone, diisobutyl ketone, methyl amyl ketone, cyclohexanone, propylene glycol monomethyl ether, propylene glycol monopropyl ether, propylene glycol monobutyl ether, and dipropylene glycol monomethyl ether.

Such solvents can be used singly, or in combination of two or more kinds thereof. The amount of blending of the solvent is not particularly limited, and is preferably adjusted so that the proportion of the solvent in the positive photosensitive resin composition is from 20% by mass to 90% by mass.

The positive photosensitive resin composition can be developed with an aqueous alkali solution such as tetramethylammonium hydroxide (TMAH).

In a case in which the composition of the disclosure is a negative photosensitive resin composition, a photo-polymerizable compound having an ethylenically unsaturated group, a thermosetting resin, and a photopolymerization initiator may be contained.

In a case in which the composition of the disclosure is a thermosetting resin composition not having development ability, a curable resin such as an epoxy resin, a curing agent such as an amine-based, acid anhydride-based, or phenolic curing agent, and, if necessary, a curing accelerator such as imidazole may be contained.

In a case in which the composition of the disclosure is a photo-curable resin composition not having development ability, a photo-polymerizable resin having a (meth)acryloyl group and a photopolymerization initiator may be contained.

All documents, patent applications, and technical standards described herein are herein incorporated by reference, as if each individual document, patent application, and technical standard were specifically and individually indicated to be incorporated by reference.

### REFERENCE SIGNS LIST

10, 30, 40, 50 airtight structure body
12 first cover substrate
14 second cover substrate
16, 52 wall member
18 airtight section
26 underlying layer
28 ALD layer

1. An airtight structure body, comprising:
an airtight section;
an underlying layer that covers an edge section of the airtight section and that comprises a resin cured product; and
an ALD layer that covers the underlying layer.

2. The airtight structure body according to claim 1, wherein a glass transition temperature of the resin cured product is from 150° C. to 400° C.

3. The airtight structure body according to claim 1, wherein a 5% weight loss temperature of the resin cured product is from 250° C. to 400° C.

4. The airtight structure body according to claim 1, wherein a storage elastic modulus at 165° C. of the resin cured product is from 10 MPa to 50 GPa.

5. The airtight structure body according to claim 1, wherein a coefficient of linear expansion of the resin cured product is from 0 ppm/K to 100 ppm/K.

6. The airtight structure body according to claim 1, wherein a difference between a coefficient of linear expansion of the resin cured product and a coefficient of linear expansion of the ALD layer is from 0 ppm/K to 30 ppm/K.

7. The airtight structure body according to claim 1, wherein the airtight section is formed by a first cover substrate, a second cover substrate, and a wall member that joins the first cover substrate and the second cover substrate to separate an inside and an outside of the airtight section.

8. The airtight structure body according to claim 7, wherein the wall member comprises a metal.

9. The airtight structure body according to claim 7, wherein the wall member comprises a resin.

10. The airtight structure body according to claim 1, wherein an interior of the airtight section is filled with an inert gas.

11. The airtight structure body according to claim 1, wherein the ALD layer comprises Al₂O₃.

12. A method of producing an airtight structure body, comprising covering an edge section of an airtight section with a curable resin composition to form a curable resin composition layer, curing the curable resin composition layer to form an underlying layer, and forming an ALD layer that covers the underlying layer.

13. The method of producing an airtight structure body according to claim 12, wherein the curable resin composition has thermosetting properties.

14. The method of producing an airtight structure body according to claim 12, wherein the curable resin composition is a positive photosensitive resin composition.

15. The method of producing an airtight structure body according to claim 12, wherein the airtight section is formed by using a first cover substrate in which a metallic first side wall frame is provided on one surface of the first cover substrate and a second cover substrate in which a metallic second side wall frame is provided on one surface of the second cover substrate, to join a top section of the first side wall frame and a top section of the second side wall frame.

16. An underlying resin composition for airtight holding, comprising a curable component.

17. The underlying resin composition for airtight holding according to claim 16, wherein the underlying resin composition is a positive photosensitive resin composition.

18. The underlying resin composition for airtight holding according to claim 16, wherein the underlying resin composition is a negative photosensitive resin composition.
